(19) United States
(12) Patent Application Publication
(10) Pub. No.: US 2025/0259894 A1
(43) Pub. Date: Aug. 14, 2025

(54) MOLYBDENUM INTEGRATION AND VOID-FREE FILL

(71) Applicant: Lam Research Corporation, Fremont, CA (US)

(72) Inventors: Matthew Bertram Edward GRIFFITHS, Campbell, CA (US); Yao-Tsung HSIEH, San Jose, CA (US); David Joseph MANDIA, Lake Oswego, OR (US); Sivananda Krishnan KANAKASABAPATHY, Pleasanton, CA (US); Chiukin Steven LAI, Sunnyvale, CA (US); Chih-Min LIN, San Jose, CA (US); Shuogang HUANG, San Jose, CA (US); Jeong-Seok NA, San Jose, CA (US); Arya SHAFIEFARHOOD, Santa Clara, CA (US)

(21) Appl. No.: 18/857,125

(22) PCT Filed: Apr. 18, 2023
(86) PCT No.: PCT/US2023/019000

§ 371 Date: Oct. 15, 2024

Related U.S. Application Data
(60) Provisional application No. 63/383,236, filed on Nov. 10, 2022.
(60) Provisional application No. 63/375,310, filed on Sep. 12, 2022.
(60) Provisional application No. 63/342,039, filed on May 13, 2022.
(60) Provisional application No. 63/332,649, filed on Apr. 19, 2022.

(51) Int. Cl. H01L 21/768; H10B 12/00

(52) U.S. Cl. CPC H01L 21/76879; H01L 21/76826; H01L 21/76844; H01L 21/76856; H10B 12/488

(57) ABSTRACT

Provided herein are methods of filling features with molybdenum (Mo) that may be used for logic and memory applications. The methods involve treating the surface of feature prior to feature fill. In some embodiments, the methods involve treating the surface of feature by exposure to a molybdenum halide. In some embodiments, the methods involve treating the surface of the feature by selective oxidation, nitridation, or halogenation. Apparatus to perform the methods are provided.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Deposition of conductive materials an integral part of many semiconductor fabrication processes. These materials may be used for horizontal interconnects, vias between adjacent metal layers, contacts between metal layers and devices, and as lines in memory devices. In an example of deposition, a tungsten (W) layer may be deposited on a titanium nitride (TiN) barrier layer to form a TiN/W bilayer by a CVD process using tungsten hexafluoride (WF₆). However, as devices shrink and more complex patterning schemes are utilized in the industry, deposition of thin tungsten films becomes a challenge. The continued decrease in feature size and film thickness brings various challenges to TiN/W film stacks. These include high resistivity for thinner films and deterioration of TiN barrier properties. Deposition in complex high aspect ratio structures such as 3D NAND structures is particularly challenging.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided herein are methods of filling features with molybdenum (Mo) that may be used for logic and memory applications.

In some embodiments, the methods involve performing treating the surface of feature by exposure to a molybdenum halide prior to feature fill.

One aspect of the disclosure relates to a method, including: providing a substrate including a feature including a metal-containing contact and dielectric sidewalls; treating the feature by exposing it to a molybdenum halide; and depositing molybdenum in the feature, wherein the deposition is selective to the metal-containing contact with respect to the dielectric sidewalls.

In some embodiments, the method further includes exposing the feature to a hydrogen-containing plasma prior to treating the feature. In some embodiments, selectively depositing molybdenum on the metal-containing bottom includes exposing the feature to a molybdenum oxyhalide. In some embodiments, the treatment inhibits molybdenum growth on the oxide or nitride sidewalls. In some embodiments, the treatment is performed without depositing molybdenum in the feature. In some embodiments, the treatment further includes exposing the feature to a co-reactant capable of reducing the molybdenum halide to form molybdenum.

In some embodiments, an amorphous molybdenum-containing layer is on the metal-containing contact. In some embodiments, the treatment removes the amorphous molybdenum-containing layer. In some embodiments, the treatment inhibits molybdenum growth on the dielectric sidewalls. In some embodiments, the method further includes removing an etch residue from the metal-containing contact prior to treating the feature.

In some embodiments, the molybdenum halide is molybdenum pentachloride (MoCl₅). In some embodiments, selective deposition is performed at a substrate temperature 250° C. to 550° C., e.g., 300° C. to 500° C.

Another aspect of the disclosure relates to molybdenum-on-molybdenum integration schemes. In some embodiments, a method includes providing a substrate including a feature having dielectric sidewalls and a molybdenum contact; including a molybdenum contact and dielectric sidewalls, wherein an amorphous molybdenum-containing layer is at the surface of the molybdenum contact; exposing the feature to a molybdenum halide to remove the amorphous molybdenum-containing layer and inhibit molybdenum deposition on the dielectric sidewalls; and depositing molybdenum in the feature, wherein the deposition is selective to the molybdenum contact with respect to the dielectric sidewalls. In some embodiments, the molybdenum halide is molybdenum pentachloride (MoCl₅). In some embodiments, depositing molybdenum in the feature includes exposing the feature to a molybdenum oxyhalide.

Methods for bottom-up fill of features on semiconductor substrates with molybdenum (Mo) include selectively treating a conformal liner layer in the feature. A portion of the liner layer on a field region and/or an upper portion of the features sidewalls is preferentially treated with respect to the liner layer on a lower portion of the sidewalls. Molybdenum is selectively deposited on the untreated or lesser treated portion.

One aspect of the disclosure relates to a method, including:
(a) providing a substrate including a field region and a feature, wherein the feature includes an opening, sidewalls, and a bottom, wherein the field region surrounds the opening, and wherein a liner layer lines the sidewalls of the feature;
(b) selectively treating the liner layer such that a portion of the liner layer on the field region and/or an upper portion of the sidewalls is preferentially treated with respect to the liner layer on a lower portion of the sidewalls, wherein selectively treating the liner layer forms selectively treated portions of the liner layer; and
(c) selectively depositing molybdenum at the bottom of the feature, wherein deposition on the selectively treated portions of the liner layer is inhibited.

In some embodiments, the liner layer is titanium nitride or tungsten nitride. In some embodiments, (a) includes depositing the liner layer in the feature. In some embodiments, the liner layer is a tungsten-containing layer or a molybdenum-containing layer. In some such embodiments, the liner layer is a tungsten layer or a molybdenum layer.

In some embodiments, (b) includes oxidation of the liner layer on the field region and/or the upper portion of the sidewalls. In some embodiments, (b) includes nitridation of the liner layer on the field region and/or the upper portion of the sidewalls. In some embodiments, (b) includes exposing the substrate to an ion beam plasma. In some such embodiments, (b) further includes rotating and tilting the substrate during exposure to the ion beam plasma.

Another aspect of the disclosure relates to a method including:
(a) providing a substrate including a field region and a feature, wherein the feature includes an opening, sidewalls, and a bottom, wherein the field region surrounds the opening, and wherein a liner layer lines the sidewalls of the feature;
(b) selectively treating the liner layer such that a portion of the liner layer on the field region and/or an upper portion of the sidewalls is preferentially treated with respect to the liner layer on a lower portion of the sidewalls to form treated regions of the liner layer; and
(c) selectively etching the treated regions of the liner layer, leaving a remaining portion of the liner layer on a lower portion of the sidewalls; and
(d) selectively depositing molybdenum at the bottom of the feature.

In some embodiments, the liner layer is titanium nitride or tungsten nitride.

In some embodiments, (a) includes depositing the liner layer in the feature. In some embodiments, the liner layer is a tungsten-containing layer or a molybdenum-containing layer. In some such embodiments, the liner layer is a tungsten layer or a molybdenum layer. In some embodiments, (b) includes oxidation of the liner layer on the field region and/or the upper portion of the sidewalls. In some embodiments, (b) includes nitridation of the liner layer on the field region and/or the upper portion of the sidewalls. In some embodiments, (b) includes exposing the substrate to an ion beam plasma. In some such embodiments, (b) further includes rotating and tilting the substrate during exposure to the ion beam plasma.

Another aspect of the disclosure relates to an apparatus including: a vacuum transfer module; a deposition module connected to the vacuum transfer module; an ion beam etching module connected to the vacuum transfer module; and a controller including machine readable instructions for: causing exposure of a substrate to an ion beam plasma in the ion beam etching module to selectively treat a liner layer of a feature on a substrate such that a portion of the liner layer on a field region and/or an upper portion of sidewalls of the feature is preferentially treated with respect to the liner layer on a lower portion of the sidewalls; causing transfer of the substrate from the ion beam etching module to the deposition module via the vacuum transfer module; and causing deposition of molybdenum in the feature in the deposition module.

These and other aspects of the disclosure are described further below with reference to the figures.

### BRIEF DESCRIPTION OF DRAWINGS

FIGS. 1A and 1B are schematic examples of material stacks that include molybdenum layers according to various embodiments.

FIGS. 2A-2L and FIG. 3 are schematic examples of various structures into which molybdenum may be deposited in accordance with disclosed embodiments.

FIG. 4 shows a schematic example of a molybdenum-on-molybdenum integration scheme.

FIG. 5 is a process flow diagram illustrating example operations in a method of filling a feature with molybdenum.

FIGS. 6A-6C show a schematic example of a feature undergoing an example of a process according to FIG. 5.

FIG. 7 shows examples of surface treatment sequences according to various embodiments.

FIG. 8 shows examples of sequences for surface treatments and selective deposition according to various embodiments.

FIG. 9 is a process flow diagram illustrating a method to fill a feature with a molybdenum (Mo) film.

FIGS. 10A-10C show a feature during various operations of filling the feature with Mo.

FIG. 11 is a plot showing film thickness after increasing numbers of atomic layer deposition (ALD) cycles of Mo deposition on both TiN and oxidized TiN (TiON).

FIG. 12 is a process flow diagram illustrating a method to fill a feature with a Mo film.

FIGS. 13A-13D show a schematic example of a method according to FIG. 12.

FIGS. 14A-14D show a schematic example of a method according to FIG. 9.

FIG. 15 shows an example of ion beam angles used to reach sidewall depths.

FIGS. 16-19 show examples of processing systems that may be used to implement the methods described herein.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

The subscripts “x” and “y” are used throughout the disclosure to denote a number greater than 0 that forms a stable compound. However, it should be noted that the lack of an “x” or other subscript (e.g., in titanium nitride (TiN) or titanium oxynitride (TiON)) does not imply a particular atomic ratio.

Provided herein are methods of filling features with molybdenum (Mo) that may be used for logic and memory applications. The Mo films may be deposited in semiconductor substrate features such as vias and trenches. The Mo films may be deposited to line features as liner layers and/or to fill features.

In some embodiments, the methods involve bottom-up deposition of Mo in a feature. Bottom-up deposition refers to growth that is mostly or wholly from a feature bottom relative to the feature sidewalls. Using conventional deposition methods to fill a feature can result in nucleation and growth on all feature surfaces. This results in conformal growth and can result in the formation of a void and/or seam in the feature. For example, a void may form as growth at the top of the feature can pinches off the feature. A seam can form in the center of a feature as film grows inward from the sidewalls. Bottom-up deposition can avoid formation of voids and seams in the feature during the fill process.

While described chiefly in the context of Mo, the methods may be used for deposition of other metals including W, Co, and Ru. For some applications, molybdenum offers several benefits over other metals such as cobalt (Co), ruthenium (Ru), and tungsten (W): (i) barrier-less and liner-less molybdenum film deposition is more feasible on oxides and nitrides as compared to deposition of cobalt, ruthenium, and tungsten, (ii) Mo resistivity scaling is better than that of tungsten, (iii) Mo intermixing with underlying Co is not expected compared to Ru intermixing with Co at temperatures less than 450° C., and (iv) there is relatively easy Mo integration into current W schemes compared to copper and ruthenium.

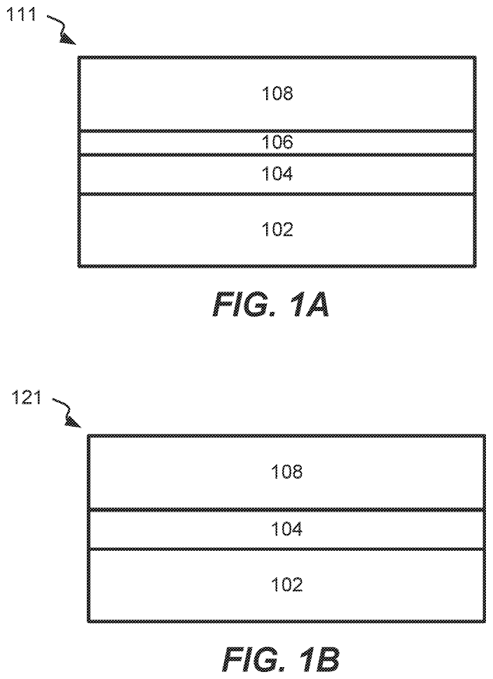

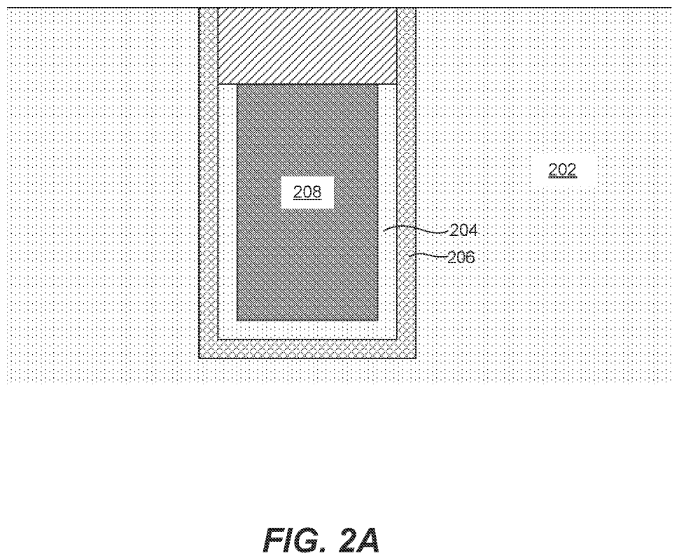

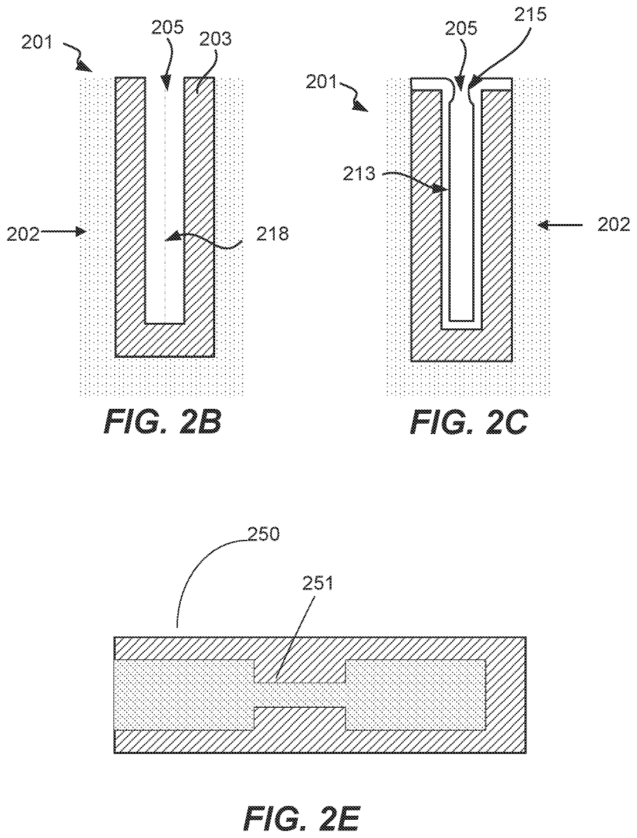

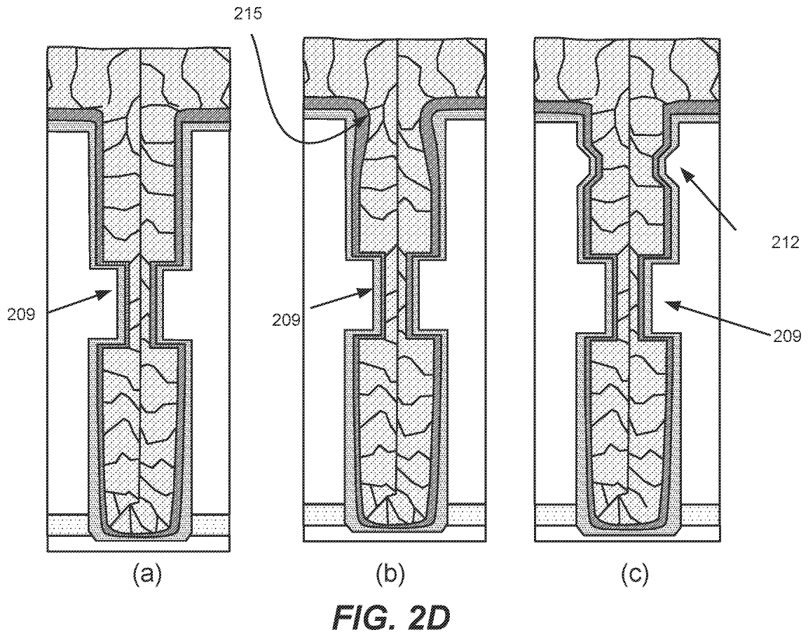

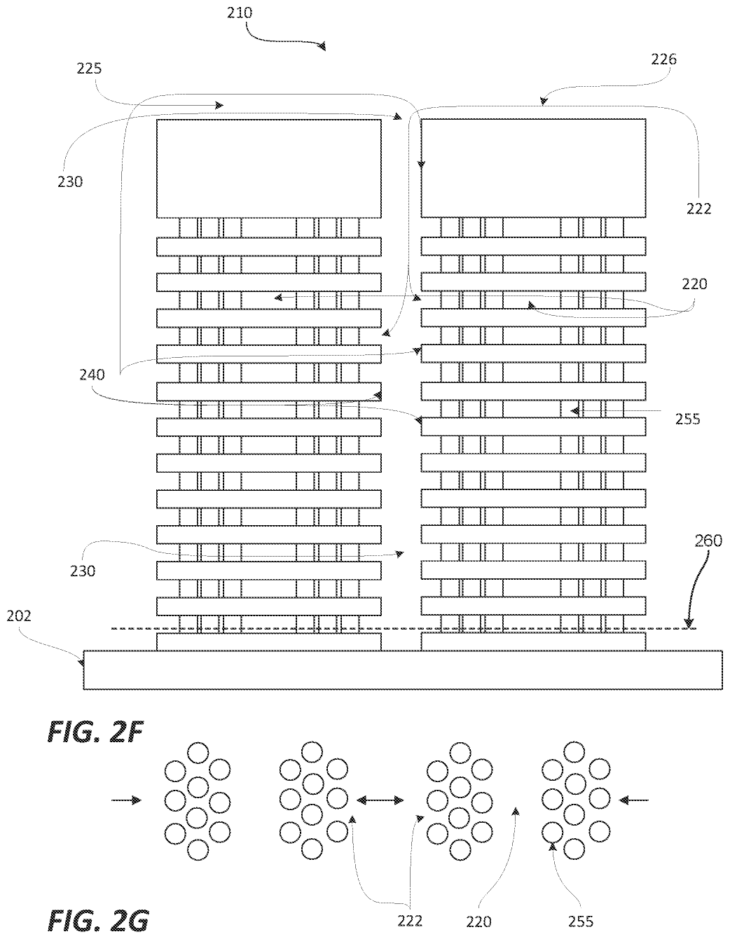

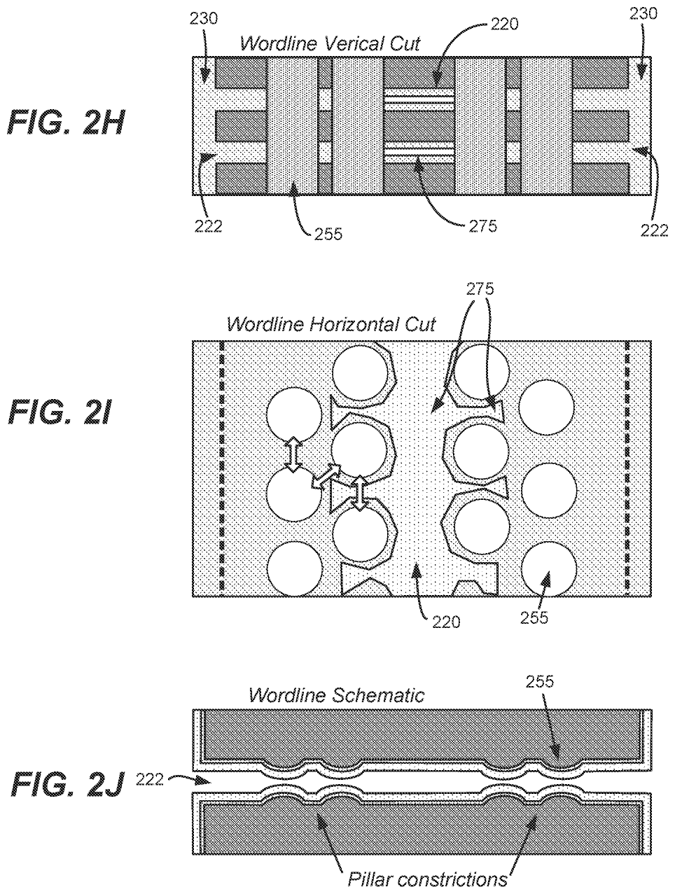

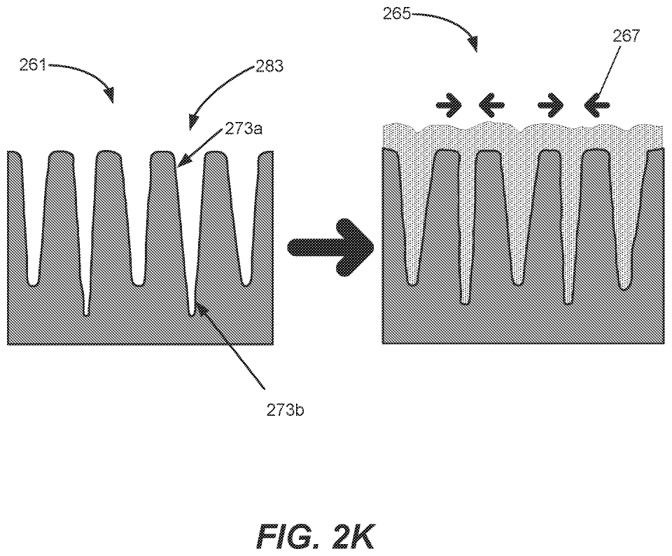

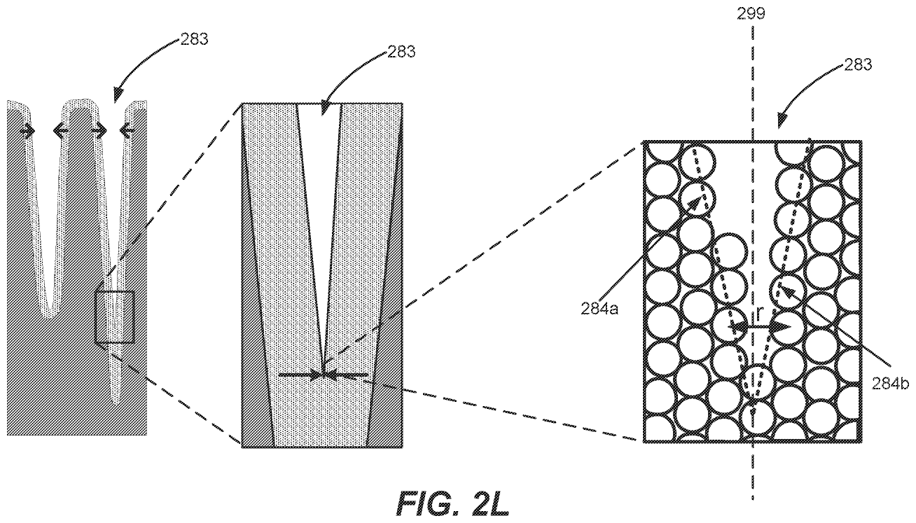

FIGS. 1A and 1B are schematic examples of material stacks that include Mo layers according to various embodiments. FIGS. 1A and 1B illustrate the order of materials in examples of particular stacks and may be used with any appropriate architecture and application, as described further below with respect to FIGS. 2A-2L, 3, 4, 6A-6C, 10A-10C, 13A-13D, and 14A-14D. FIG. 1A shows a first material stack 111 featuring a substrate 102 and a molybdenum layer 108 deposited thereon. The substrate 102 may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. In some embodiments, the substrate 102 may be or include silicon (Si) or silicon germanium (SiGe). The methods may also be applied to form metallization stack structures on other substrates, such as glass, plastic, and the like.

The stack 111 has a dielectric layer 104 on the substrate 102. The dielectric layer 104 may be deposited directly on a semiconductor surface (e.g., a Si or SiGe surface) of the substrate 102, or there may be any number of intervening layers. For example, the substrate 102 may include any number of layers deposited in various arrangements on a semiconductor surface.

Examples of dielectric layers include doped and undoped silicon oxide, silicon nitride, and aluminum oxide layers, with specific examples including doped or undoped layers of silicon nitride (SiN), silicon dioxide (SiO₂), and aluminum oxide (Al₂O₃). The stack 111 has a layer 106 disposed between the molybdenum layer 108 and the dielectric layer 104. The layer 106 may be a diffusion barrier and/or an adhesion layer, for example. A diffusion barrier is a layer that prevents diffusion of species between layers. An adhesion layer is a layer that promotes adhesion of a layer to an underlying layer. Examples of diffusion barrier and adhesion layers include titanium nitride (TiN), titanium/titanium nitride (Ti/TiN), tungsten (W), tungsten nitride (WN), and tungsten carbon nitride (WCN). The molybdenum layer 108 is the main conductor of the structure. In some embodiments, the molybdenum layer 108 may include multiple bulk layers deposited at different conditions. The molybdenum layer 108 may or may not include a molybdenum nucleation layer. In the depicted example of FIG. 1A, the molybdenum layer 108 is deposited directly on the layer 106. In other embodiments (not depicted), the molybdenum layer 108 may be deposited on a separate layer such as a growth initiation layer that includes another material, such as a tungsten (W) or W-containing growth initiation layer. The growth initiation layer may be used to facilitate nucleation and growth of the molybdenum layer 108.

FIG. 1B shows another example of a stack 121. In this example, the stack 121 includes the substrate 102, dielectric layer 104, with molybdenum layer 108 deposited directly on the dielectric layer 104, without an intervening diffusion barrier or adhesion layer. The molybdenum layer 108 is as described with respect to FIG. 1A. By using molybdenum as the main conductor, low resistivity thin films can be obtained. Examples of low resistivity thin films include films with resistivity less than 40 uOhm-cm at 60 angstroms thickness and less than 15 uOhm-cm at 200 angstroms thickness.

In some embodiments, a stack (not shown) may include the substrate, a conductive layer, and a molybdenum layer deposited onto the conductive layer. As used herein, a conductive layer is a layer having a conductivity of at least 10⁴ Ω⁻¹-cm⁻¹ at room temperature. Examples include molybdenum on a metal layer (e.g., a W layer, or another Mo layer). In these embodiments, there is no dielectric layer between the molybdenum layer and the conductive layer. Similarly, the stack may include molybdenum deposited directly on a metal compound layer. Examples include molybdenum on a metal nitride layer (e.g., TiN, WN, or MoN). In still some other embodiments of a stack (not shown), the stack may include a substrate and a molybdenum layer deposited directly on the substrate, including directly on a semiconducting surface, on a dielectric surface, or on a conductive surface. FIGS. 1A and 1B illustrate examples of the order of materials in a particular stack and may be used with any appropriate architecture and application, with examples described further below with respect to FIGS. 2A-2L, 3, 4, 6A-6C, 10A-10C, 13A-13D, and 14A-14D.

The methods described herein are performed on a substrate that may be housed in a chamber. The substrate may be a silicon or other semiconductor wafer, including wafers having one or more layers of material, such as dielectric, conducting, or semiconducting material deposited thereon. The methods are not limited to semiconductor substrates and may be performed to fill any feature with molybdenum.

Substrates may have features such as vias or contact holes, which may be characterized by one or more narrow and/or re-entrant openings, constrictions within the feature, and high aspect ratios. A feature may be formed in one or more of the above-described stacks or layers within a stack. For example, the feature may be formed at least partially in a dielectric layer. In some embodiments, a feature may have an aspect ratio of at least about 2:1, at least about 4:1, at least about 6:1, at least about 10:1, at least about 25:1, or higher. One example of a feature is a hole or via in a semiconductor substrate or a layer on the substrate.

FIG. 2A depicts a schematic example of a DRAM architecture, including a Mo buried wordline (bWL) 208 in a silicon substrate 202. The Mo bWL is formed in a trench etched in the silicon substrate 202. Lining the trench is a conformal barrier layer 206 and an insulating layer 204. The conformal barrier layer 206 is disposed between the insulating layer 204 and the silicon substrate 202. In this example, the insulating layer 204 may be a gate oxide layer formed from a high-k dielectric material such as a silicon oxide or silicon nitride material. In some embodiments disclosed herein, the conformal barrier layer 206 is TiN or a tungsten-containing layer, such as WN or WCN layer. In some embodiments, a conformal tungsten-containing growth initiation layer (not shown) may be present between the conformal barrier layer 206 and the molybdenum bWL 208. Alternatively, the molybdenum bWL 208 may be deposited directly on a TiN or other diffusion barrier. In some embodiments, one or both of layers 204 and 206 is not present.

The bWL structure shown in FIG. 2A is one example of an architecture that includes a molybdenum fill layer. During fabrication of the bWL, molybdenum is deposited into a feature that may be defined by an etched recess in the silicon substrate 202 that is conformally lined with layers 206 and/or 204, if present.

FIGS. 2B-2H are additional schematic examples of various structures into which molybdenum may be deposited in accordance with disclosed embodiments. FIG. 2B shows an example of a cross-sectional depiction of a vertical feature 201 to be filled with Mo. The feature can include a feature hole 205 in a silicon substrate 202. The feature hole 205 may have an underlayer 203 lining the sidewall or interior of the feature hole 205 and may form the interior surfaces. The feature hole 205 or other feature may have a dimension near the opening, e.g., an opening diameter or line width of between about 10 nm to 500 nm, for example, between about 25 nm and about 300 nm. The feature hole 205 can be referred to as an unfilled feature or simply a feature. The vertical feature 201, and any feature, may be characterized in part by an axis 218 that extends through the length of the feature, with vertically-oriented features having vertical axes and horizontally-oriented features having horizontal axes. The underlayer 203 can be, for example, a diffusion barrier layer, an adhesion layer, a nucleation layer, a combination of thereof, or any other applicable material. Non-limiting examples of underlayers can include dielectric layers and conducting layers. Examples of dielectric materials include oxides, such as SiO₂ and Al₂O₃; nitrides, such as SiN; carbides, such as nitrogen-doped silicon carbide (NDC) and oxygen-doped silicon carbide (ODC); and low k dielectrics, such as carbon-doped SiO₂. In particular implementations, an underlayer can be one or more of titanium, titanium nitride, tungsten nitride, titanium aluminide, tungsten, and molybdenum. In some embodiments, the under-layer is tungsten-free. In some embodiments, the underlayer is molybdenum-free.

In some embodiments, features are wordline features in a 3D NAND structure. For example, a substrate may include a wordline structure having an arbitrary number of wordlines (e.g., 50 to 450) with vertical channels at least 200 Å deep. Examples of wordline features are described further below. Another example of a feature is a trench in a substrate or layer. Features may be of any depth. In various embodiments, the feature may have an underlayer, such as a barrier layer or adhesion layer. Non-limiting examples of underlayers include dielectric layers and conducting layers, e.g., silicon oxides, silicon nitrides, silicon carbides, metal oxides, metal nitrides, metal carbides, and metal layers.

FIG. 2C shows an example of a vertical feature 201 that has a re-entrant profile. A re-entrant profile is a profile that narrows from a bottom, closed-end, or interior of the feature to the feature opening. According to various implementations, the profile may narrow gradually and/or include an overhang at the feature opening. FIG. 2C shows an example of the latter, with an underlayer 213 lining the sidewall or interior surfaces of the feature hole 205. Similar to FIG. 2B, the underlayer 213 can be a diffusion barrier layer, an adhesion layer, a nucleation layer, a combination of thereof, or any other applicable material. Non-limiting examples of under-layers can include dielectric layers and conducting layers. The underlayer 213 forms an overhang 215 such that the underlayer 213 is thicker near the opening of the vertical feature 201 than inside the vertical feature 201.

In some implementations, features having one or more constrictions within the feature may be filled. FIG. 2D shows examples of views of various filled features having constrictions. Each of the examples (a), (b), and (c) in FIG. 2D includes a constriction 209 at a midpoint within the feature. The constriction 209 can be, for example, between about 15 nm-20 nm wide. Constrictions can cause pinch off during deposition of molybdenum in the feature using conventional techniques, with deposited metal blocking further deposition past the constriction before that portion of the feature is filled, resulting in voids in the feature. Example (b) further includes an overhang 215 (such as, a liner/barrier overhand) at the feature opening. Such an overhang could also be a potential pinch-off point. Example (c) includes a constriction 212 further away from the field region than the overhang 215 in example (b).

Horizontal features, such as in 3-D memory structures, can also be filled. FIG. 2E shows an example of a horizontal feature 250 that includes a constriction 251. For example, horizontal feature 250 may be a word line in a 3-D NAND (also referred to as vertical NAND or VNAND) structure. In some implementations, the constrictions can be due to the presence of pillars in a 3D NAND or other structure. FIG. 2F presents a cross-sectional side view of a 3-D NAND structure 210 (formed on a silicon substrate 202) having 3-D NAND stacks (left 225 and right 226), central vertical structure 230, and a plurality of stacked horizontal wordline features 220 with openings 222 on opposite sidewalls 240 of central vertical structure 230. Note that FIG. 2F displays two “stacks” of the exhibited 3-D NAND structure 210, which together form the “trench-like” central vertical structure 230. However, in certain embodiments, there may be more than two such stacks arranged in sequence and running spatially parallel to one another, the gap between each adjacent pair of stacks forming a central vertical structure 230, like that explicitly illustrated in FIG. 2F. In this embodiment, the horizontal wordline features 220 are 3-D memory wordline features that are fluidically accessible from the central vertical structure 230 through the openings 222. Although not explicitly indicated in the figure, the horizontal wordline features 220 present in both the 3-D NAND stacks 225 and 226 shown in FIG. 2F (i.e., the left 3-D NAND stack 225 and the right 3-D NAND stack 226) are also accessible from the other sides of the stacks (far left and far right, respectively) through similar vertical structures formed by additional 3-D NAND stacks (to the far left and far right, but not shown). Each 3-D NAND stack 225, 226 contains a stack of wordline features that are fluidically accessible from both sides of the 3-D NAND stack through a central vertical structure 230. In the particular example schematically illustrated in FIG. 2F, each 3-D NAND stack contains 6 pairs of stacked wordlines. However a 3-D NAND memory layout may contain any number of vertically stacked pairs of wordlines.

The wordline features in a 3-D NAND stack can be formed by depositing an alternating stack of silicon oxide and silicon nitride layers, and then selectively removing the nitride layers leaving a stack of oxides layers having gaps between them. These gaps are the wordline features. Any number of wordlines may be vertically stacked in such a 3-D NAND structure so long as there is a technique for forming them available, as well as a technique available to successfully accomplish (substantially) void-free fills of the vertical features. Thus, for example, a VNAND stack may include between 2 and 512 horizontal wordline features, between 2 and 256 horizontal wordline features, between 8 and 128 horizontal wordline features, or between 16 and 64 horizontal wordline features, and so forth (the listed ranges understood to include e the recited endpoints).

FIG. 2G presents a cross-sectional top-down view of the same 3-D NAND structure 210 shown in the side view in FIG. 2F with the cross-section taken through the horizontal section 260 as indicated by the dashed horizontal line in FIG. 2F. The cross-section of FIG. 2G illustrates several rows of pillars 255, which are shown in FIG. 1F to run vertically from the base of the substrate 202 to the top of the 3-D NAND structure 210. In some embodiments, the pillars 255 are formed from a polysilicon material and are structurally and functionally significant to the 3-D NAND structure 210. In some embodiments, such polysilicon pillars may serve as gate electrodes for stacked memory cells formed within the pillars. The top-view of FIG. 2G illustrates that the pillars 255 form constrictions in the openings 222 to wordline features 220. Fluidic accessibility of wordline features 220 from the central vertical structure 230 via openings 222 (as indicated by the arrows in FIG. 2G) is inhibited by pillars 255. In some embodiments, the size of the horizontal gap between adjacent polysilicon pillars is between about 1 and 20 nm. This reduction in fluidic accessibility increases the difficulty of uniformly filling wordline features 220 with material. The structure of wordline features 220 and the challenge of uniformly filling them with molybdenum material due to the presence of pillars 255 is further illustrated in FIGS. 2H, 2I, and 2J.

FIG. 2H exhibits a vertical cut through a 3-D NAND structure similar to that shown in FIG. 2F, but here focused on a single pair of wordline features 220 and additionally schematically illustrating a fill process which resulted in the formation of a void 275 in the filled wordline features 220. FIG. 2I also schematically illustrates void 275, but in this figure illustrated via a horizontal cut through pillars 255, similar to the horizontal cut exhibited in FIG. 2G. FIG. 2J illustrates the accumulation of molybdenum material around the constriction-forming pillars 255, the accumulation resulting in the pinch-off of openings 222, so that no additional molybdenum material can be deposited in the region of voids 275. Apparent from FIGS. 2H and 2I is that void-free molybdenum fill relies on migration of sufficient quantities of deposition precursor down through central vertical structure 230, through openings 222, past the constricting pillars 255, and into the furthest reaches of wordline features 220, prior to the accumulated deposition of molybdenum around pillars 255 causing a pinch-off of the openings 222 and preventing further precursor migration into wordline features 220. Similarly, FIG. 2J exhibits a single wordline feature 220 viewed cross-sectionally from above and illustrates how a generally conformal deposition of molybdenum material begins to pinch-off the interior of wordline feature 220 due to the fact that the significant width of pillars 255 acts to partially block, and/or narrow, and/or constrict what would otherwise be an open path through wordline feature 220. (It should be noted that the example in FIG. 2J can be understood as a 2-D rendering of the 3-D features of the structure of the pillar constrictions shown in FIG. 2I, thus illustrating constrictions that would be seen in a plan view rather than in a cross-sectional view.)

Three-dimensional structures may need longer and/or more concentrated exposure to precursors to allow the innermost and bottommost areas to be filled. Three-dimensional structures can be particularly challenging when employing molybdenum halide and/or molybdenum oxyhalide precursors because of their proclivity to etch, with longer and more concentrated exposure allowing for more etch as parts of the structure.

FIGS. 2K and 2L show examples of an asymmetric trench structure DRAM bWL. Some fill processes for DRAM bWL trenches can distort the trenches such that the final trench width and resistance Rs are significantly non-uniform. FIG. 2K shows an unfilled feature 261 and filled feature 265 that exhibits line bending after fill. In this example, the features are a narrow asymmetric trench structure DRAM bWL. As shown, multiple features 283 are depicted on a substrate. These features 283 are spaced apart, and in some embodiments, adjacent features have a pitch between about 20 nm and about 60 nm or between about 20 nm and 40 nm. The pitch is defined as the distance between the middle axis of one feature to the middle axis of an adjacent feature. The unfilled features 261 may be generally V-shaped, as shown in feature 283, having sloped sidewalls where the width of the feature narrows from the top of the feature to the bottom of the feature. The features widen from the feature bottom 273b to the feature top 273a. After some fill operations, line bending may be observed within the filled feature 265. In some situations, a cohesive force between opposing surfaces of a trench pulls the trench sides together, as depicted by arrows 267. This phenomenon is illustrated in FIG. 2L and may be characterized as “zipping up” the feature. As the feature 283 is filled, more force is exerted from a center axis 299 of the feature 283, causing line bending. For example, molybdenum may be deposited on the sidewalls of the feature 283. Deposited molybdenum 284a and 284b on sidewalls of feature 283 thereby interact in close proximity, where molybdenum-molybdenum bond radius r is small, thereby causing cohesive interatomic forces between the smooth growing surfaces of molybdenum and pulling the sidewalls together, thereby causing line bending.

Provided below are methods of filling features with molybdenum. The methods described herein include surface treatment and deposition operations, which may be used to fill substrate features such as those described above. As described above, molybdenum offers several benefits over other metals. Examples of feature fill for horizontally-oriented and vertically-oriented features are described below. It should be noted that in at least most cases, the examples are applicable to both horizontally-oriented and vertically-oriented features. Horizontally-oriented features generally refer to features oriented such that the feature axis is parallel to the plane of the substrate surface. Vertically-oriented features generally refer to features oriented such that the feature axis is orthogonal to the plane of the substrate surface.

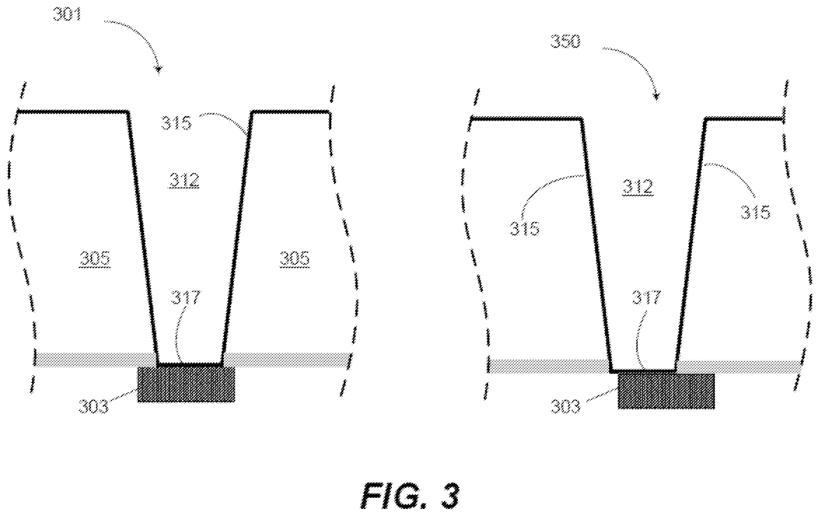

Methods of filling features that include exposing a feature to a molybdenum halide prior to feature fill are described with reference to FIG. 3-8. As described, the molybdenum halide can etch, deposit, and/or otherwise treat material on the feature bottom and/or sidewalls.

In some embodiments, the methods are used to fill features to contact an underlying metal. An example of such a feature is shown in FIG. 3. At 301, an unfilled feature 312 is shown. The unfilled feature 312 is formed in an oxide layer 305 and is to be filled with Mo to make contact with an underlying metal 303. The unfilled feature 312 is defined by sidewall surfaces 315 and bottom surface 317.

According to various embodiments, the sidewall surfaces 315 and the bottom surface 317 may be the same or different materials. In some embodiments, the oxide layer 305 may be exposed to form the sidewall surfaces 315. Similarly, the underlying metal 303 may be exposed to form the bottom surface 317. In some embodiments, surface oxidation may result in the bottom surface 317 being a metal oxide. In some embodiments, a liner layer (not shown) may be formed on the sidewall and/or bottom of the feature to form the sidewall surfaces 315 and/or bottom surface 317. Examples of liner layers include TiN, WN, and WCN. In some embodiments, a liner layer may be a molybdenum-containing liner layer such as a molybdenum nitride (MoN) layer.

In some embodiments, the sidewall surfaces 315 and bottom surface 317 are different. In a subsequent deposition operation, Mo may be deposited at conditions under which it preferentially nucleates on the bottom surface 317. This can promote bottom-up fill and prevent the formation of voids.

Examples of underlying metals and/or bottom surfaces include TiN, titanium aluminum carbide (TiAlC), W, Co, Mo, Ru, Cu, nickel (Ni), iridium (Ir), rhodium (Rh), tantalum (Ta), and titanium (Ti) and tantalum nitride (TaN).

The methods described herein address various challenges that occur as feature size decreases. For example, void-free gap fill becomes more challenging in small features due to deeper features, re-entrant profiles near the feature openings, and/or insufficient growth selectivity between feature bottom metal surfaces and sidewall dielectric surfaces. Smaller features can lead to more frequent pattern misalignment. An example of a misaligned feature is shown at 350 in which the unfilled feature 312 is not centered over the underlying metal 303. As a result, the bottom surface 317 includes metal and dielectric material.

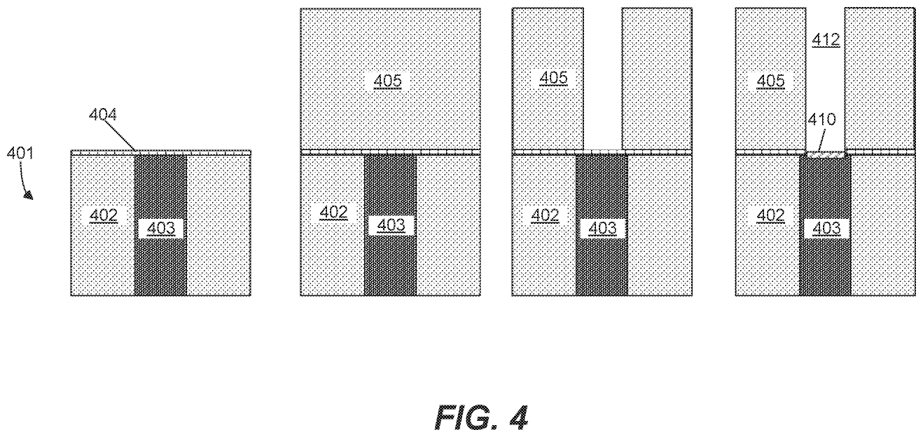

In some embodiments, the methods may be used in molybdenum-on-molybdenum integration schemes. An example of such an integration scheme is shown in FIG. 4. A layer 401 includes dielectric 402 and Mo 403. An etch stop layer (ESL) 404 is disposed over the layer 401. The ESL 404 may be SiN, for example. A dielectric layer 405 is deposited over the ESL 404. The dielectric layer 405 is then patterned and etched, with the etch stopping at the ESL 404 (not shown). The ESL 404 is then removed from the feature 412 forming the unfilled feature 412.

A Mo-containing layer 410 may formed at the surface of Mo 403 during the previous processing operations. The Mo-containing layer 410 is generally an amorphous layer. It is relatively thin, e.g., on the order of 0.5 nm to 3 nm. It may contain various impurities such as oxygen, nitrogen, and/or other halogens. While surface oxidation can be removed by a hydrogen (H₂) plasma, the Mo-containing layer 410 is generally resistant to H₂ plasma. If left in the device, it can cause higher resistance at the interface between Mo 403 and the subsequently deposited Mo film.

Aspects of the disclosure relate to a surface treatment performed prior to deposition of Mo in a feature. According to various embodiments, the surface treatment involves exposure to a molybdenum halide. In some embodiments, the molybdenum halide is provided without a co-reactant, and no deposition occurs. In some embodiments, the molybdenum halide is provided with a co-reactant. A thin layer of Mo may be deposited.

In some embodiments, the feature includes dielectric surfaces such as dielectric sidewall surfaces. The surface treatment may inhibit growth on the dielectric surfaces, enhancing selectivity during subsequent deposition on the conductive surfaces. In some embodiments, the feature as provided includes a Mo-containing layer as described above. The surface treatment can remove this layer, yielding a clean Mo surface for deposition and Mo—Mo interconnect formation.

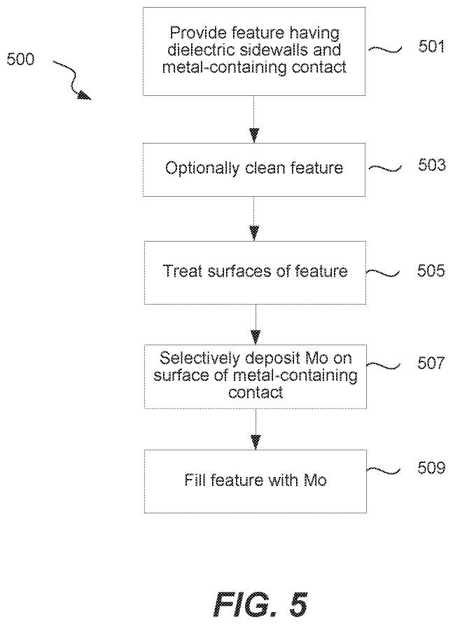

FIG. 5 is a process flow diagram illustrating example operations in a method of filling a feature with molybdenum. The process begins with an operation 501 in which a feature having dielectric sidewalls and a metal-containing contact provided. The metal-containing contact may be at the bottom of the feature with the dielectric sidewalls extending from the feature opening to the metal-containing contact. The feature may be provided to a processing chamber. In some embodiments, one or more processing operations may occur in the processing chamber to form the feature having dielectric sidewalls and a metal-containing containing contact.

Examples of dielectric sidewalls include silicon-containing layers such as oxides and nitrides. Examples of metal-containing contacts include metals and metal compound films. The metal-containing contact may be generally conductive, having a conductivity of at least 10⁴ Ω⁻¹-cm⁻¹ at room temperature. Examples include TiN, TiAlC, W, Co, Mo, Ru, Cu, Ni, Rh, Ir, Ta, Ti, and TaN.

In some embodiments, a surface oxide is present on the metal-containing contact. Still further, in some embodiments, a layer containing other impurities is present on the metal-containing contact. An example is an amorphous Mo-containing layer described as with reference to FIG. 4.

In some embodiments, an etch operation to remove a liner layer from at least the sidewalls of the feature is performed prior to operation 501. For example, a feature may include a TiN liner layer conformally coating the bottom and sidewalls. An etch may be performed to remove the TiN layer from the sidewalls, exposing dielectric material. The sidewall surfaces are then silicon oxide or other dielectric material.

In an operation 503, an optional clean is performed. Operation 503 can remove surface oxide and/or etch residue, for example. Examples of etch residue include fluorocarbons and hydrocarbon polymers. In some embodiments, operation 503 involves exposure to a reducing plasma such as a H₂ plasma. In some embodiments, operation 503 treats the dielectric sidewalls. For example, it may remove organic materials and/or reduce oxygen in the dielectric sidewalls. This can improve subsequent Mo growth selectivity on the metal-containing surface.

In operation 505, a surface treatment is performed. The surface treatment involves exposure to a molybdenum halide gas. This is typically a plasma-free operation. Plasma-free refers to the operation performed without activating a plasma. As discussed further below, operation 505 may or may not involve deposition of molybdenum.

In embodiments in which an amorphous Mo-containing layer as described above with respect to FIG. 4 is present, operation 505 removes all or at least a portion of the layer. In the same or other embodiments, operation 505 inhibits nucleation on the dielectric sidewall surfaces. In some embodiments, operation 503 is performed after operation 505.

The process continues at operation 507 with selective deposition of Mo on the metal-containing contact. In some embodiments, this operation involves reaction using a molybdenum halide or a molybdenum oxyhalide precursor. The process may continue with fill of the feature with Mo in an operation 509. The same or different Mo precursor may be used for operations 507 and 509.

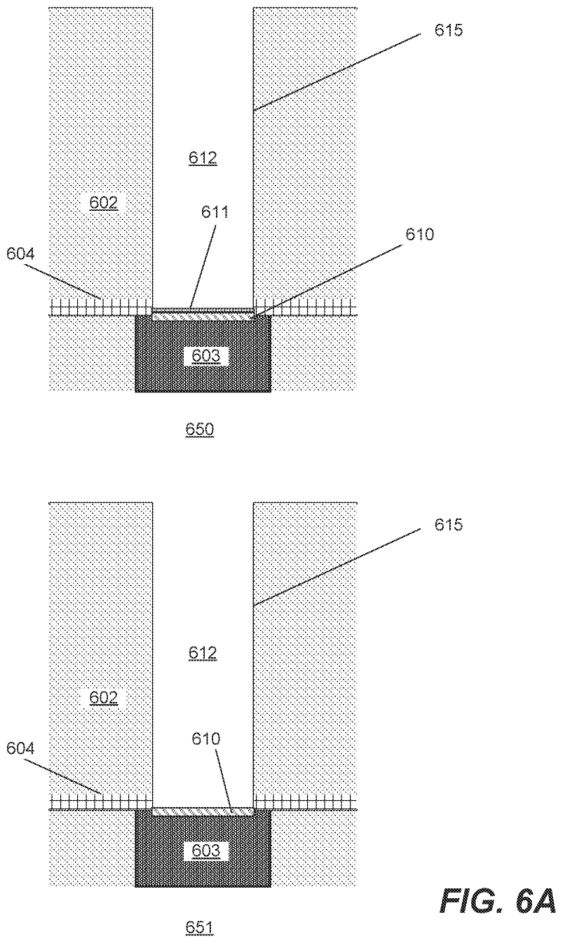

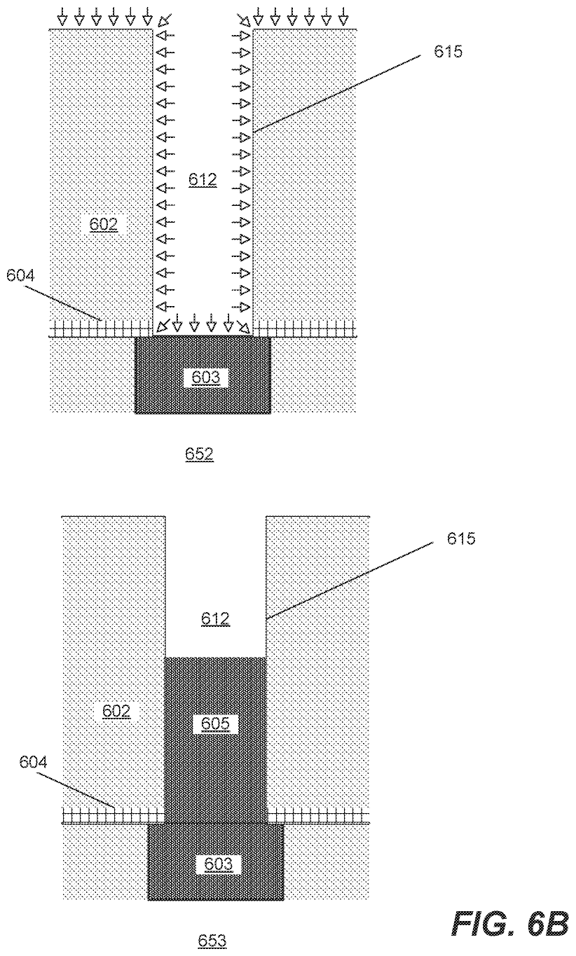

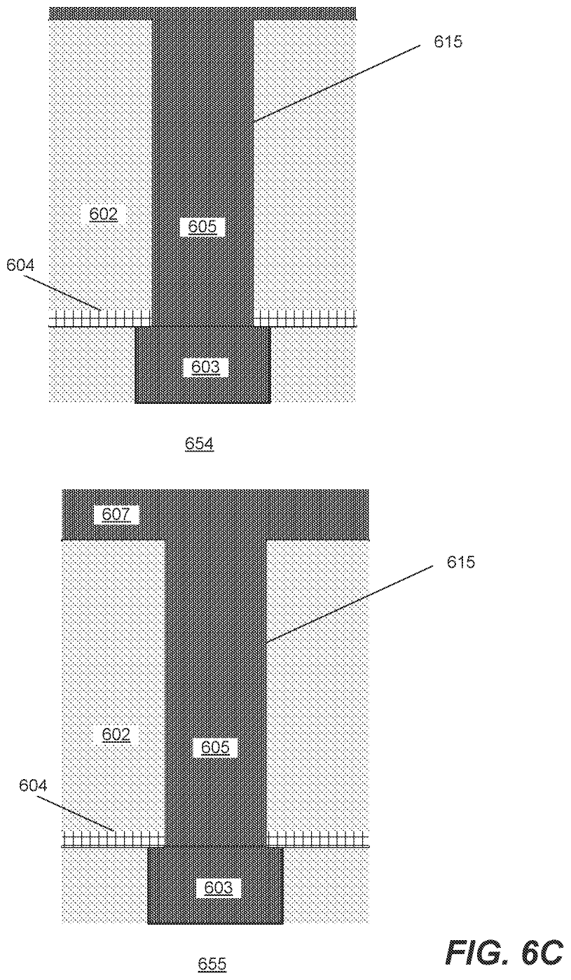

FIGS. 6A-6C show a schematic example of a feature 612 undergoing an example of a process according to FIG. 5. First, in FIG. 6A, at 650, the feature 612 including a metal-containing contact 603 and dielectric sidewalls 615 is shown. In this example, the metal-containing contact 603 is a Mo contact. Molybdenum will be deposited in the feature 612 to make contact with the Mo contact. An amorphous Mo-containing interfacial layer 610 and surface oxide 611 are shown. The surfaces of the dielectric sidewalls 615 are silicon oxide in this example. Etch stop layer (ESL) 604 is also shown.

At 651, the feature is shown after operation 503 is performed. An H₂ plasma is used to remove the surface oxide 611. As discussed above, this operation also treats the dielectric sidewalls 615 in a manner that improves subsequent selectivity of Mo growth on metal-containing contact 603.

Turning to FIG. 6B, at 652, the feature 612 is shown undergoing a surface treatment described above with respect to operation 505 of FIG. 5. The amorphous Mo-containing interfacial layer 610 is removed. As illustrated by the arrows, the treatment also affects the oxide surfaces, inhibiting subsequent Mo nucleation.

At 653, the feature is shown after a selective deposition as described above with respect to operation 507 of FIG. 5. Bottom-up, non-conformal fill is observed. Mo 605 is grown from the underlying metal-containing contact 603 with no or significantly less growth from the sidewall surfaces. As a result, Mo 605 does not have a seam or void.

In FIG. 6C, at 654, the feature is shown after completion of fill of the feature as described above with respect to operation 509 of FIG. 5. The remaining fill may be bottom-up or conformal. Overburden deposition of Mo 607 is shown at 655.

According to various embodiments, a surface treatment as described above with reference to operation 505 of FIG. 5 involves exposure to a molybdenum halide. In some embodiments, a molybdenum chloride compound is used. Molybdenum-containing compounds are also referred to herein as Mo-containing precursors or Mo precursors. Molybdenum chlorides are given by the formula MoClₓ, where x is 2, 3, 4, 5, or 6, and include molybdenum dichloride (MoCl₂), molybdenum trichloride (MoCl₃), molybdenum tetrachloride (MoCl₄), molybdenum pentachloride (MoCl₅), and molybdenum hexachloride (MoCl₆). In some embodiments, MoCl₅ or MoCl₆ are used. While the description chiefly refers to MoClₓ compounds, in other embodiments, other molybdenum halides may be used. Molybdenum halide precursors are given by the formula MoX_{z}, where X is a halogen (fluorine (F), chlorine (Cl), bromine (Br), or iodine (I)) and z is 2, 3, 4, 5, or 6. Examples of MoX_{z} precursors include molybdenum fluoride (MoF₆). In some embodiments, a non-fluorine-containing MoX_{z} precursor is used to prevent fluorine etch or incorporation. In some embodiments, a non-bromine-containing and/or a non-iodine-containing MoX_{z} precursor is used to prevent etch or bromine or iodine incorporation.

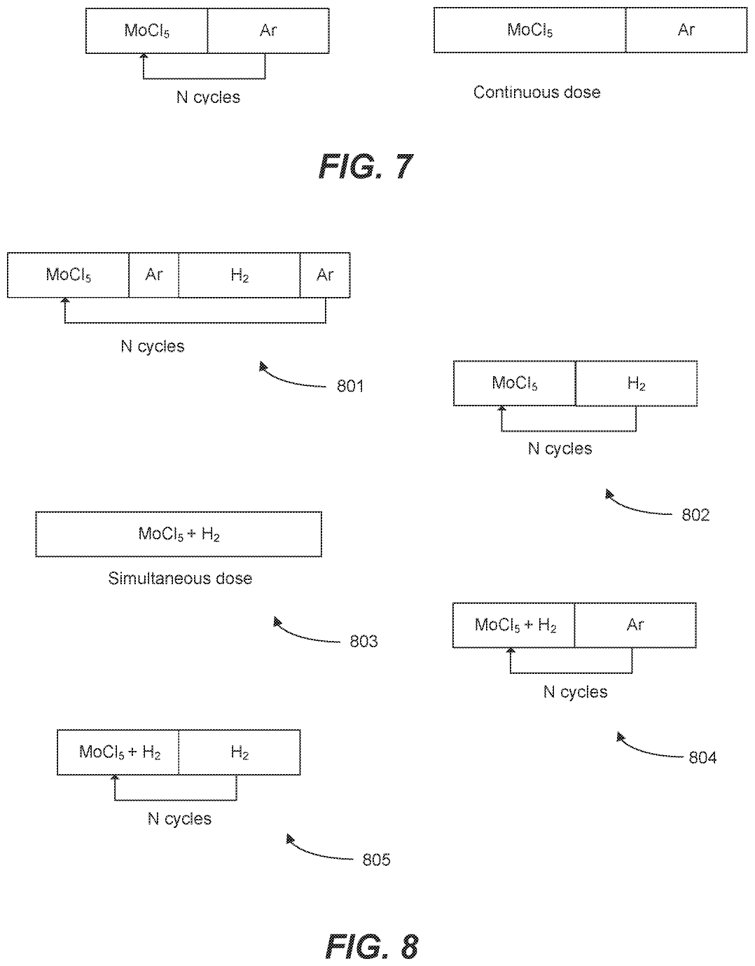

In some embodiments, operation 505 involves exposure to the molybdenum halide compound without a co-reactant gas. In such embodiments, the precursor may be pulsed or delivered in a continuous dose. FIG. 7 shows two examples of surface treatment sequences. In the first MoCl₅ is pulsed with argon (Ar) other inert gas for N cycles. In the second, a continuous dose of MoCl₅ is delivered followed by an Ar purge.

In some embodiments, operation 505 involves exposure to the molybdenum halide compound with a co-reactant gas to deposit Mo. The co-reactant is generally H₂, though other reducing agents as described below may be used. FIG. 8 shows examples of surface treatment sequences. In example sequence 801, MoCl₅ pulses are alternated with H₂ pulses with intervening purge gas pulses. In example sequence 802, MoCl₅ pulses are alternated with H₂ pulses with no intervening purge gas pulses. In another example sequence (not pictured), MoCl₅ pulses are alternated with H₂ pulses with a purge gas pulse directly after only one of the reactant gases in each cycle. In the third example sequence 803, MoCl₅ is flowed with H₂. In the further example sequence 804, the co-flowed reactants are pulsed with an alternating Ar pulse. In another example sequence 805, H₂ gas may be flowed into the chamber and is continuously flowing into the chamber while MoCl₅ is intermittently flowing into the chamber. In FIGS. 7 and 8, another molybdenum halide and/or another inert gas may be used instead of MoCl₅ and Ar, respectively.

In some embodiments, a surface treatment as shown in FIG. 8 (with a co-reactant to deposit Mo) may be employed when metals besides Mo are at the feature bottom. In such embodiments, a Mo surface layer may be formed facilitating subsequent Mo growth. For example, if a W, Co, or Ru layer is at the feature bottom, a surface treatment as shown in FIG. 8 may be used to form a thin Mo surface layer.

In example processes, Mo was deposited using a molybdenum oxychloride (MoO₂Cl₂) on two surfaces after treatment: a) silicon dioxide deposited from tetraethyl orthosilicate (TEOS oxide) and b) TiN. Deposition occurred after the treatments described in the below table. A first treatment involved an H₂ plasma only, a second treatment included H₂ plasma followed a molybdenum chloride treatment, and a third treatment included an H₂ plasma followed by molybdenum chloride and hydrogen treatment. The table below shows the total thickness of the Mo deposited in Angstroms.

| | | H₂ plasma | H₂ plasma |
|---|---|---|---|
| | | preclean + | preclean + |
| | H₂ plasma | 30 pulses MoClₓ | 40 cycles |
| | preclean only | surface treatment | MoClₓ/H₂ |
| 1 kÅ TEOS oxide | 98 | 6 | 11 |
| 50 Å PVD TiN | 173 | 188 | 209 |
| Selectivity ratio | 1.8 | 31 | 19 |

Both molybdenum halide surface treatments resulted in significant nucleation delay on silicon dioxide compared to TiN. Both surface treatments also increased deposition on Mo. Deposition was also performed to evaluate feature fill. Without the surface treatment (pre-clean only), voids were observed due to lack of selectivity. Void-free gap fill was observed for both surface treatments.

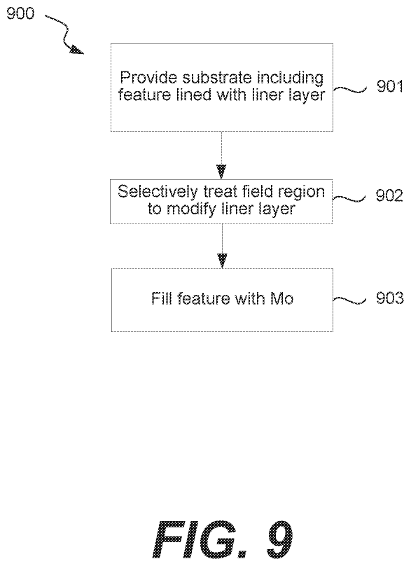

Another aspect of the disclosure relates to methods of filling features with metal that involve selective treatment of sidewalls of a feature prior to deposition. These methods are described with reference to FIGS. 9-15 below. The methods may be used in addition to or without the molybdenum halide treatment described above.

FIG. 9 is a process flow diagram illustrating a method to fill a feature with a Mo film according to certain embodiments. Examples of applications include middle-of-line (MOL) interconnects and back end of line (BEOL) interconnects. In one example, the methods may be used for source/drain contact fill. Method 900 begins with providing a substrate including a feature in which Mo is to be deposited in an operation 901. The substrate may be provided to a semiconductor processing tool.

The feature may be a trench or via that is formed in a dielectric layer. Examples of dielectric materials include oxides, such as silicon oxide (SiO₂) and aluminum oxide (Al₂O₃); nitrides, such as silicon nitride (SiN); carbides, such as nitrogen-doped silicon carbide (NDC) and oxygen-doped silicon carbide (ODC); and low k dielectrics, such as carbon-doped SiO₂. Mo may be deposited in the feature to make electrical contact to an underlying layer. Examples of underlying layers include metals, metal silicides, and semiconductors. Examples of metals include Co, Ru, Cu, W, Mo, nickel (Ni), iridium (Ir), rhodium (Rh), tantalum (Ta), and titanium (Ti). Examples of metal silicides include titanium silicide (TiSiₓ), nickel silicide (NiSiₓ), molybdenum silicide (MoSiₓ), cobalt silicide (CoSiₓ), platinum silicide (PtSiₓ), ruthenium silicide (RuSiₓ), and nickel platinum silicide (NiPt_{y}Siₓ). Examples of semiconductors include silicon (Si), silicon germanium (SiGe), and gallium arsenide (GaAs), with or without semiconductor dopants such as carbon (C), arsenic (As), boron (B), phosphorus (P), tin (Sn), and antimony (Sb).

The feature generally has sidewalls with sidewall surfaces and a bottom with a bottom surface. The sidewalls may be made of one or more layers. The sidewall extends from the field region to the bottom. The feature bottom may extend from a first sidewall in the feature to a second sidewall in the feature and may be made of one or more layers. The sidewall surface is the exposed area on the sidewall and may change during wafer processing. For example, the sidewall surface may change from a first material to a second material after the second material is deposited onto the sidewall. Similarly, the bottom surface is the exposed area on the bottom and may change during wafer processing. In some embodiments, the sidewall surfaces may be the same material as the bottom surface. For example, in some embodiments, the sidewall surfaces and the bottom surface as provided are TiN. In some embodiments, the material of the sidewall surfaces may be different than the material of the bottom surface. For example, the bottom surface may be a metal silicide and the sidewall surface may be a silicon oxide, such as SiO₂.

Prior to any Mo deposition, a liner layer may line the unfilled feature and form the sidewall surfaces and/or bottom surface. In some embodiments, a liner layer lines the whole feature and forms the sidewall surfaces and bottom surface. In some other embodiments, the liner layer lines only a portion of the feature. For example, a TiN layer may line the sidewalls with the bottom surface unlined. In some embodiments, a liner layer is a diffusion barrier and/or an adhesion layer. Examples of materials for liner layers include metal nitrides (e.g., a TiN or tantalum nitride (TaN) barrier layer) and metals (e.g., a Ti adhesion layer).

In some embodiments, the bottom and sidewall surfaces are oxidized. Oxidation may be caused by exposing a feature's surfaces to air or other oxidizing conditions. For example, a metal silicide (MSiₓ where M is a metal) surface may be oxidized to oxidized metal silicide (MSiₓO_{y}) on exposure to air. Other examples of oxidized surfaces include oxidized metal nitrides (MNₓO_{y}), oxidized silicon (SiOₓ), and oxidized silicon-germanium (SiGeOₓ).

In some embodiments, oxidizing conditions occur incidentally during substrate processing or transfer operations. In some embodiments, an intentional oxidation is performed as described further below.

In some embodiments, the liner layer is a conformal metal layer such as a conformal W or Mo layer. This is described further below.

In an operation 902, the liner layer is treated selectively such that the field region and/or at least an upper portion of the sidewalls are treated without treating the bottom surface or treating it only to lesser extent.

According to various embodiments, operation 902 may involve selective oxidation or nitridation of the field region and/or upper sidewalls of the feature. Also in some embodiments, operation 902 involves selective halogenation of the field region and/or upper sidewalls of the feature.

In some embodiments, operation 902 involves selective oxidation of the field region and/or upper sidewalls of the feature. For example, a TiN layer may be oxidized to form titanium oxynitride (TiON). In another example, a Mo or W liner layer is oxidized to form a MoOₓ or WOₓ layer.

In some embodiments, operation 902 involves selective nitridation of the field region and/or upper sidewalls of the feature. In an example, a Mo or W liner layer is treated to form a MON or WN layer. Other examples of layers that may be formed include tungsten carbonitride (WCN) and molybdenum carbide (MoC).

In some embodiments, operation 902 involves selective halogenation of the field region and/or upper sidewalls of the feature. In an example, a Mo or W liner layer is treated to form a MoX_{y} or WX_{y} layer, where X is any halogen and y is a number between 0 and 3, endpoints included. In another example, a MoN_{z} or WN_{z} is treated to form a MoN_{z}X_{y} or WN_{z}X_{y} layer, where X is any halogen and y is a number between 0 and 3, endpoints included, and z is a number between 0 and 2, endpoints included. In another example, a MoC_{z} or WC_{z} is treated to form a MoC_{z}X_{y} or WC_{z}X_{y} layer, where X is any halogen and y is a number between 0 and 3, endpoints included, and z is a number between 0 and 2, endpoints included. In another example, MoO_{z} or WO_{z} is treated to form MoO_{z}X_{y} or WO_{z}X_{y}, where X is any halogen and y is a number between 0 and 3, endpoints included, and z is a number between 0 and 2, endpoints included.

In some embodiments, operation 902 selectively inhibits subsequent deposition on the treated surfaces. In some embodiments, operation 902 is followed by an etch of the treated liner layer. These approaches provide differential deposition surfaces, facilitating selective deposition at the bottom of the feature and bottom-up fill.

The feature is then filled with Mo in an operation 903. Deposition of Mo is described further below.

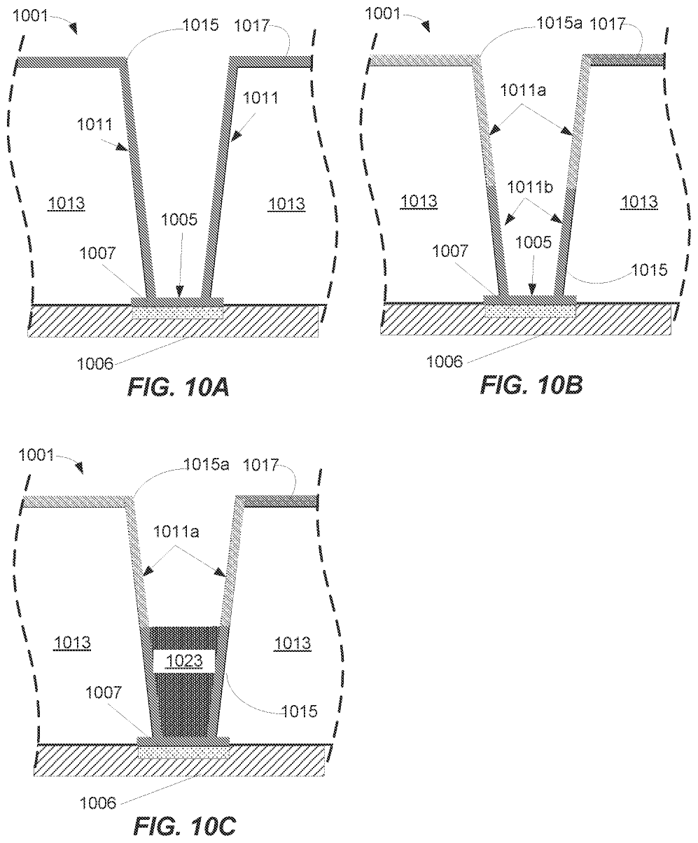

FIG. 10A shows an example of a feature to be filled with Mo in certain embodiments. A feature 1001 having a titanium nitride (TiN) liner layer 1015 is shown. The feature 1001 is formed in a dielectric material 1013 to connect to an underlying metal silicide (MSiₓ) 1007. The underlying MSiₓ is connected to a semiconductor layer 1006, e.g., silicon (Si) or silicon-germanium (SiGe). This stack may be used in a transistor junction structure.

One example of a MSiₓ layer is titanium silicide (TiSiₓ). The TiN liner layer 1015 lines the feature 1001. The TiN liner layer 1015 is a diffusion barrier layer used on top of a metal silicide such as TiSiₓ in trench contacts for source/drain applications. One purpose of the TiN layer 1015 is to prevent the MSiₓ from any potential reaction with the overlying metal. Another purpose is to protect the MSiₓ or other layer from a fluorine attack. Yet another purpose is to prevent the MSiₓ from being oxidized in air or during subsequent processing. In the example of FIG. 10A, the TiN layer 1015 is on the feature sidewalls 1011, feature bottom 1005, and field region 1017 of the feature 1001. Deposition of a metal such as molybdenum in the feature 1001 can result in Mo nucleating on all areas. As the film grows, it can result in pinch-off at the top of the feature, preventing further reactant diffusion in the feature and causing formation of a void. This occurs in features such as depicted in FIG. 10A, as well as in other features having uniform sidewall and bottom surfaces.

FIG. 10B shows the feature 1001 after selective oxidation to form TiON layer 1015a on the field region 1017 and an upper sidewall portion 1011a. TiN liner layer 1015 remains on the bottom surface 1005 as well as lower sidewall portion 1011b. The concentration of oxygen in the TiON layer may be a gradient decreasing with feature depth.

FIG. 10C shows the feature 1001 after deposition of Mo. Nucleation of the Mo film is inhibited on the TiON layer 1015a. This allows the Mo to grow from the feature bottom 1005, resulting in bottom-up deposition of bulk Mo 1023. The fill may continue to fully fill the feature 1001.

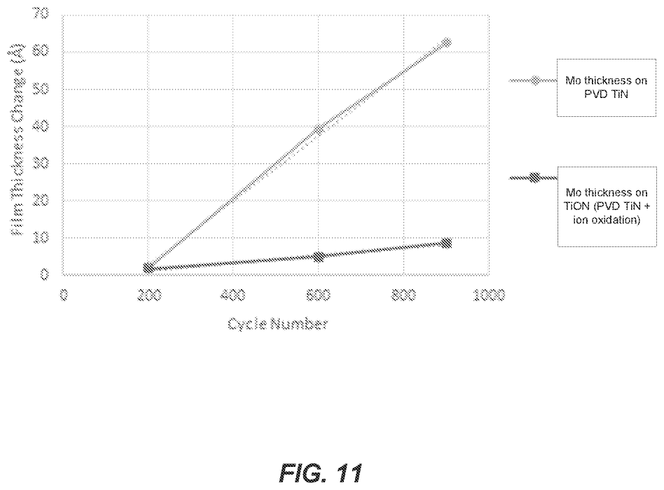

FIG. 11 is a plot showing film thickness after increasing numbers of ALD cycles of Mo deposition on both TiN and oxidized TiN (TiON). As can be seen from FIG. 11, Mo growth is inhibited on TiON. The TiN is deposited by physical vapor deposition (PVD).

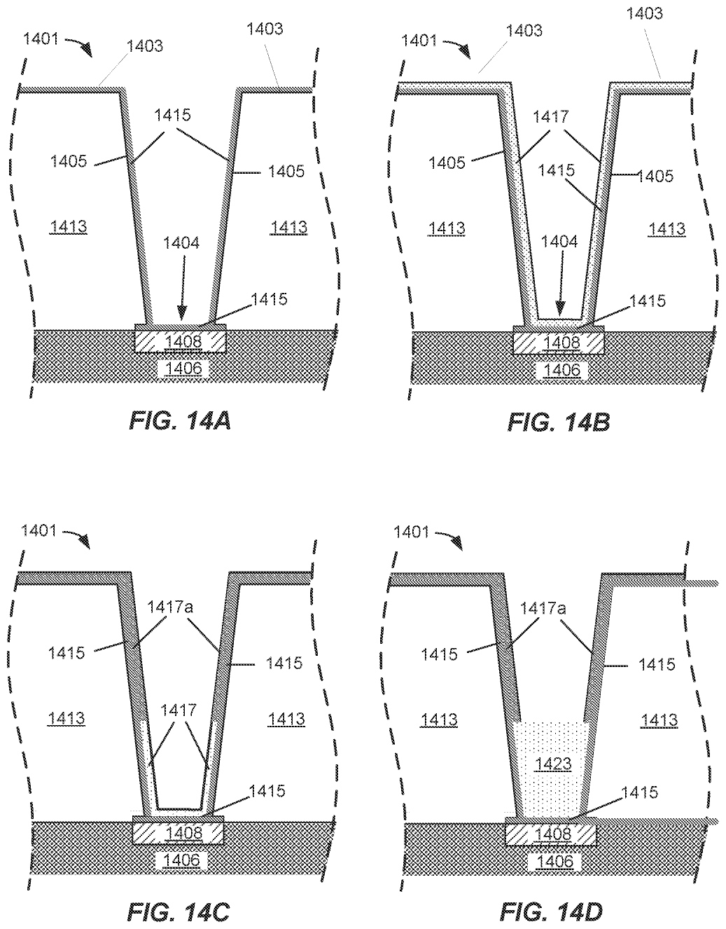

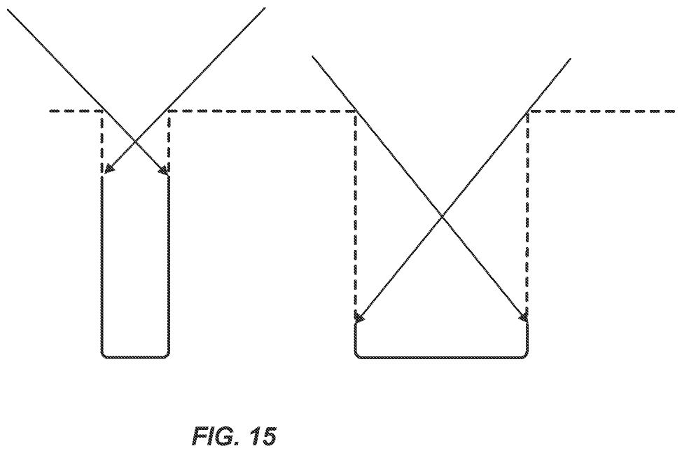

In some embodiments, prior to selective oxidation, a liner layer of a metal or metal-containing film such as Mo, MON, W, WCN, or WN is conformally deposited in a feature. It may be deposited on a TiN layer or other liner layer if present or may be the first liner layer in the feature. It is selectively oxidized to form a metal oxide layer, similarly to the TiON layer in FIG. 2B, followed by selective deposition in the bottom portion of the feature. An example is described further below with respect to FIGS. 14A-14D.

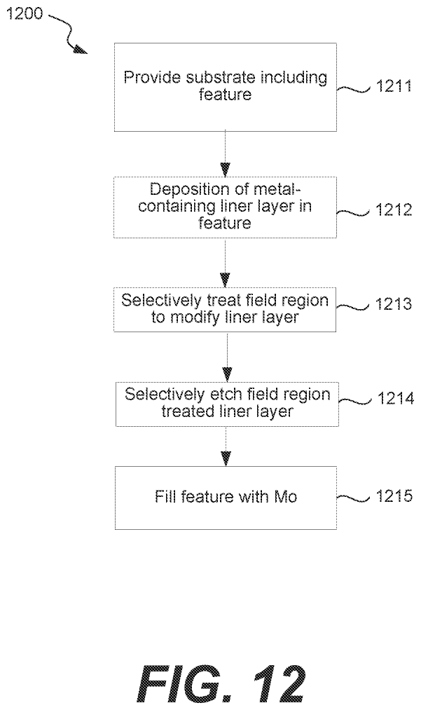

FIG. 12 is a process flow diagram illustrating a method 1200 to fill a feature with a Mo film. A substrate including a feature is provided in an operation 1211. The feature is to be filled with Mo. Operation 1211 may be as described above with respect to operation 901 with FIG. 9. In an operation 1212, a conformal metal-containing liner layer is deposited in the feature. A field region and/or upper portion of the sidewalls is treated in an operation 1213. According to various embodiments, this can involve oxidation and/or nitridation of the field region and/or upper region of the sidewalls. In an operation 1214, the treated regions are selectively etched. Operation 1214 may involve exposure to a molybdenum halide compound as described further below. The result is to remove the conformal metal-containing layer from the treated regions. This can expose the dielectric sidewalls. Molybdenum is then deposited in the feature as described above with respect to operation 903 of FIG. 9.

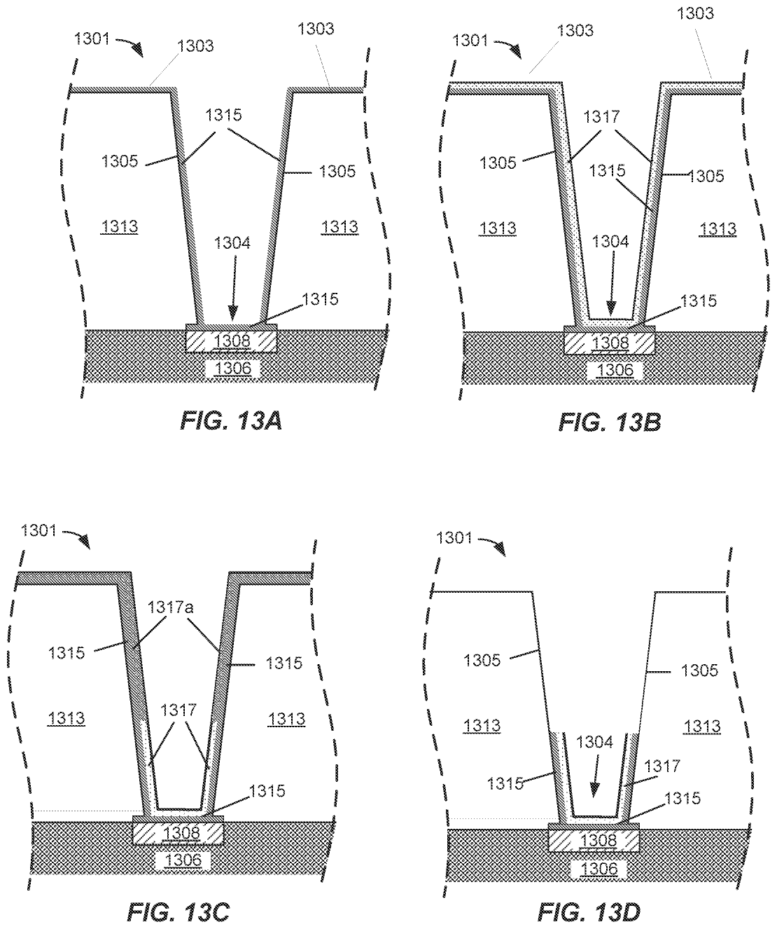

FIGS. 13A-13D show a schematic example of a method according to FIG. 12. In FIG. 13A, a feature 1301 formed in a dielectric layer 1313 is shown. It includes dielectric sidewalls 1305 and a feature bottom 1304. A field region 1303 surrounds the feature opening. A conformal liner layer 1315 lines the feature 1301, including lining the dielectric sidewalls 1305 and the feature bottom 1304. In some embodiments, conformal liner layer 1315 may be a diffusion barrier such as a TiN layer. Metal is to be deposited in the feature 1301 to contact metal silicide layer 1308 in layer 1306. Metal silicide layer may be a titanium (TiSiₓ) layer, for example. Layer 1306 may be a semiconductor layer such as a Si or SiGe layer.

FIG. 13B shows the feature 1301 after deposition of a conformal metal-containing liner layer 1317 in the feature. In the example of FIG. 13B, the conformal metal-containing liner layer 1317 overlies conformal liner layer 1315.

FIG. 13C shows the feature 1301 after selective treatment of the field region and the upper sidewalls of the metal-containing liner layer 1317 to form treated conformal metal-containing liner layer 1317a on the field region and upper sidewalls and untreated conformal metal-containing liner layer 1317 on the lower sidewalls and feature bottom.

FIG. 13D shows the feature 1301 after an etch removes the conformal liner layer 1315 and the treated conformal metal-containing liner layer 1317a from the upper sidewalls and field region. This operation exposed the dielectric sidewalls 1305 of the feature 1301, leaving the liner layer 1315 (e.g., TiN layer) and metal-containing liner layer 1317 (e.g., Mo or W layer) on the feature bottom 1304 and the lower sidewalls.

FIGS. 14A-14D show a schematic example of another method according to FIG. 9. FIGS. 14A-14C are similar to FIGS. 13A-13C, with deposition of a conformal metal-containing liner layer 1417 on a conformal liner layer 1415. In FIG. 14B, in some embodiments, a layer 1417 may be a conformal Mo or W layer which may be deposited on a TiN layer or other diffusion barrier. FIG. 14C shows the feature 1401 after selective treatment as described above with respect to FIG. 14C.

FIG. 14D shows the feature 1401 after deposition of metal. Nucleation of the metal film is inhibited on the treated metal-containing liner layer 1417a. This allows the metal to grow from the feature bottom 1404, resulting in bottom-up deposition of bulk metal 1423. The fill may continue to fully fill the feature.

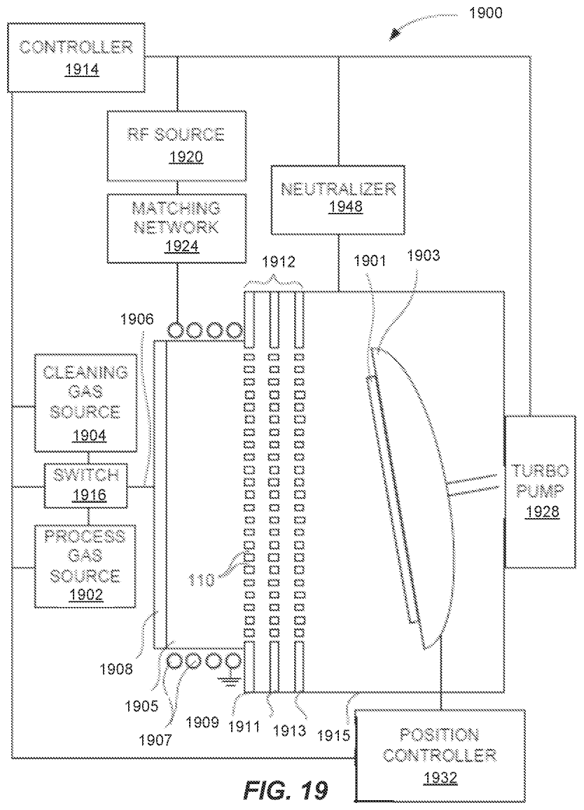

In some embodiments, selective oxidation or nitridation of a field region and upper portion of a feature involves a mild oxygen or nitrogen ion bombardment in an ion-beam etching system. An example of an ion beam etching system as described in the FIG. 19 below. In such a system, a substrate may be tilted and rotated appropriately to control the angle of incidence of the ions and thus the selective oxidation. See FIG. 15, which shows an example of ion beam angles to reach sidewall depths. By appropriately tilting and rotating a substrate, the ion beam can be directed to selectively oxidize or nitridize sidewalls and/or field regions.

The field area and upper sidewalls of a patterned wafer can be selectively oxidized without removing any material. In the case of a TiN film, TiON can be formed at the field and (if desired) upper sidewall areas, but TiN will remain un-oxidized at the bottom of the feature. In the case of a conformal Mo, W, or other metal film which has been previously deposited over top of a TiN film, MoOₓ, WOₓ, or other metal oxide can be formed at the field area and, if desired, upper sidewall, but Mo, W, or other metal will remain un-oxidized at the bottom of the feature.

The field area and upper sidewalls of a patterned wafer can be selectively halogenated as described above using a halogen gas source. Examples of gases include chorine (Cl₂), bromine (Br₂), iodine (I₂), hydrogen bromide (HBr), and hydrogen iodide (HI). Each of these may be provided in a mixture with an inert gas (e.g., Ar) and/or H₂ with examples of mixtures including Ar/Cl₂, Ar/Br₂, Ar/I₂, Ar/HBr, Ar/HI, H₂/Cl₂, H₂/Br₂, H₂/I₂, H₂/HBr, and H₂/HI. When halogenated, the surface becomes passivated and inhibits deposition.

In some embodiments, a growth surface may be restored after an etch or deposition operation. For example, after an operation 902 in Figure or operation 1214 in FIG. 12, a film may be de-halogenated, de-oxidized, or de-nitridized. For example, to restore the original growth surface, halogenated layer can be treated by exposure to a H₂ gas or plasma and/or etched. A variety of etch chemistries can be used, including thermal and plasma O₂, N₂, Cl₂, and molybdenum halides, to restore the original growth surface. These techniques may also be used after selective oxidation or selective nitridation to restore the original growth surface.

In one example, a process can involve selective treatment of a film, followed by deposition or etch of Mo, followed by restoration (e.g., dehalogenation), followed by deposition or etch of Mo.

In some embodiments, selective treatment (e.g., oxidation, nitridation, or halogenation) does not include ion-bombardment. For example, exposure to plasma generated from an appropriate source gas may be used. The plasma may be capacitively-coupled or inductively-coupled according to various embodiments. It may be remotely-generated or generated in-situ. Such exposures may take place without tilting a substrate.

For example, a low-power, biased oxygen, nitrogen, or halogen plasma may be used in a high-pressure system without tilting the substrate. If pressure is high enough (above 2 Torr), the bottom of the feature will remain un-treated. In some embodiments, an ion-beam etching system described with reference to FIG. 19 provides greater control over treatment depth. Selective nitridation may be performed by either of the methods described above but using a mild nitrogen plasma. Selective halogenation may be performed by either of the methods described above but using a mild halogen plasma.

In some embodiments, a selective treatment profile is modulated inside features by tuning the ratio of H₂ gas and treatment gas (oxidation, nitridation, or halogenation gas) at the plasma exposure operations. Plasma ions are more dominant on the field/upper sidewall whereas H₂ radicals are more dominant at bottom, enabling selective treatment on features.

### Molybdenum Deposition

In the methods described herein, molybdenum deposition may be performed after the treatments described above with reference to FIGS. 4-15. Deposition of molybdenum as described herein involves reacting a Mo-containing precursor, also referred to as a molybdenum precursor. In some embodiments, a molybdenum halide compound as described above is used. In methods including surface treatment using a molybdenum halide compound, the same or different compound may be used for deposition.

In some embodiments, a Mo precursor is a molybdenum chloride (MoClₓ) compound also referred to as a molybdenum chloride precursor or MoClₓ precursor. For example, operations 507 and/or 509 in FIG. 5, operation 903 in FIG. 9, or operation 1215 in FIG. 12 may use a molybdenum oxyhalide precursor. Molybdenum chloride precursors are given by the formula MoClₓ, where x is 2, 3, 4, 5, or 6, and include molybdenum dichloride (MoCl₂), molybdenum trichloride (MoCl₃), molybdenum tetrachloride (MoCl₄), molybdenum pentachloride (MoCl₅), and molybdenum hexachloride (MoCl₆). In some embodiments, MoCl₅ or MoCl₆ are used. While the description chiefly refers to MoClₓ precursors, in other embodiments, other molybdenum halide precursors may be used. Molybdenum halide precursors are given by the formula MoX₇, where X is a halogen (fluorine (F), chlorine (Cl), bromine (Br), or iodine (I)) and z is 2, 3, 4, 5, or 6. Examples of MoX_{z} precursors include molybdenum fluoride (MoF₆). In some embodiments, a non-fluorine-containing MoX_{z} precursor is used to prevent fluorine etch or incorporation. In some embodiments, a non-bromine-containing and/or a non-iodine-containing MoX_{z} precursor is used to prevent etch or bromine or iodine incorporation.

In some embodiments, the feature may be filled using a molybdenum oxyhalide precursor. For example, operations 507 and/or 509 in FIG. 5, operation 903 in FIG. 9, or operation 1215 in FIG. 12 may use a molybdenum oxyhalide precursor. Molybdenum oxyhalide precursors are given by the formula MoO_{y}X_{z}, where X is a halogen (fluorine (F), chlorine (Cl), bromine (Br), or iodine (I)), and y and z are numbers greater than 0 such that MoO_{y}X_{z} forms a stable compound. Examples of molybdenum oxyhalides include molybdenum dichloride dioxide (MoO₂Cl₂), molybdenum tetrachloride oxide (MoOCl₄), molybdenum tetrafluoride oxide (MoOF₄), molybdenum dibromide dioxide (MoO₂Br₂), and the molybdenum iodides MoO₂I, and Mo₄O₁₁I. It should be understood that as used herein the term molybdenum oxyhalide precursor may refer to a molybdenum oxyhalide precursor as described above or a molybdenum-containing oxyhalide precursor that includes molybdenum, oxygen, a halide and one or more other elements. In some embodiments, molybdenum oxyhalide or molybdenum-containing oxyhalides may include multiple different halogens (e.g., F and Cl and/or I and/or Br, etc.). A feature may be filled with molybdenum using a MoClₓ precursor, MoO_{y}X_{z} precursor, or a combination thereof.

For deposition of molybdenum into the feature, the molybdenum precursor may be reacted with a co-reactant. Examples of co-reactants include hydrogen (H₂), silane (SiH₄), diborane (B₂H₆), germane (GeH₄), ammonia (NH₃), and hydrazine (N₂H₄).

In some embodiments, deposition of molybdenum may use a plasma-based process. Gas may be fed into a remote or in-situ plasma generator to generate plasma species. Examples of gas that may be used to generate plasma may be a hydrogen-containing gas, such as H₂, nitrogen-containing gas, such as nitrogen (N₂) and other gases, such as Ar and NH₃. The plasma species may be inert or react with the molybdenum precursor to form a film.

A feature may be filled with molybdenum by atomic layer deposition (ALD) or chemical vapor deposition (CVD). Thermal ALD or plasma enhanced ALD (PEALD) may be used. Similarly, thermal CVD or plasma enhanced CVD (PECVD) may be used.

ALD is a surface-mediated deposition technique in which doses of a precursor and a reactant are sequentially introduced into a deposition chamber. One or more cycles of sequential doses of a molybdenum precursor and reactant may be used to deposit Mo. For example, in the deposition of an initial molybdenum layer (e.g., as in operation 505 or 507 of FIG. 5), MoCl₅ may be used as a precursor and H₂ as a reducing agent. Doses of MoCl₅ and H₂ are sequentially introduced into the deposition chamber with a purge gas, such as argon, flowed between. For ALD, the temperature of the substrate and the pressure of the chamber may be controlled. For example, the substrate may be heated between 200° C. and 800° C., e.g., between 250° C. and 550° C. or between 300° C. and 500° C. between 350° C. and 450° C. In some embodiments, the chamber may be pressurized between 10 Torr and 200 Torr, e.g., between 50 Torr and 90 Torr. In some embodiments, the temperature and/or pressure may be used to control the rate of reactions. In some embodiments, the temperature and/or pressure may be used to control selectivity.

In some embodiments, molybdenum fill may involve CVD. In a CVD process, the molybdenum precursor and reactant are in vapor phase together in the deposition chamber. Generally speaking, a CVD process fills a feature faster than an ALD process. In one example, the precursor may be a molybdenum oxychloride, such as MoO₂Cl₂, and is flowed into the chamber with a reactant, such as H₂. In this example, the wafer is simultaneously exposed to the precursor and reactant, which react and fill features with Mo.

In still some other embodiments, a feature may be filled using a pulsed CVD process. The pulsed CVD process continuously flows a reactant into a chamber while pulses of a precursor flow into the chamber. For example, H₂ gas may be flowed into the chamber and is continuously flowing into the chamber while the molybdenum-containing precursor is intermittently flowing into the chamber. The temperature of the substrate and pressure in the chamber may be controlled during a CVD operation.

Molybdenum may be selectively deposited into a feature using the methods described herein. Selective deposition refers to preferential deposition on a first material with respect to a second material. Molybdenum deposition and growth may be easier on a metal material relative to molybdenum deposition and growth on a dielectric material. For example, a feature may have a sidewall surface of SiO₂ and a TiN plug in a bottom portion of the feature. In selective deposition, molybdenum is deposited into the feature and may grow on the TiN plug but not grow (or grow to a lesser extent) on the SiO₂ sidewall surfaces.

Process conditions such as the precursor gas, the reducing agent, process temperature, process pressure, and exposure time may affect the selectivity of the molybdenum film being deposited. Different precursor gases may have different process windows in which molybdenum film may be selectively deposited. Generally speaking, MoCl₅ gas has a large process window, i.e., large temperature and pressure range, where the precursor gas retains its selectivity. For example, MoCl₅ may be selectively deposited on a metal material with respect to a dielectric material where the process temperature is 200° C. to 800° C., e.g., 250° C. to 550° C., or 300° C. to 500° C. Generally speaking, higher process temperatures and higher process pressures reduce the selectivity of the deposited gas. For example, at higher temperatures, a precursor gas such as MoCl₅ may lose its selectivity and deposit molybdenum film on both a metal surface and a dielectric surface within a feature.

MoCl₅ may be reacted with different reactant to deposit a molybdenum film. Described below are examples of deposition of molybdenum film within a feature using a MoCl₅ precursor and different process controls. In a first example, the MoCl₅ precursor is reacted with a hydrogen (H₂) reactant using the deposition methods described above. In the description herein, the metal precursors are reacted with H₂ as a co-reactant (also referred to as a hydrogen reactant or H₂ reactant). However, other reactants may be used instead of hydrogen including other hydrogen-containing reactants such SiH₄, B₂H₆, NH₃, as appropriate. While reactants such as B₂H₆ and/or SiH₄ are stronger reducing agents, they can also result in higher resistivity. Thus, in some embodiments, using H₂ as described herein is advantageous. Process temperatures for selective deposition of the molybdenum film may be between 200° C. to 800° C., e.g., 250° C. to 550° C., or 300° C. to 500° C. At these temperatures, the molybdenum film is selectively deposited on conductive metal or metal compound surfaces, such as a TiN surface, in a feature relative to dielectric surfaces. The molybdenum film grows from the locations where the conductive surfaces are located in a feature. If the conductive surface is a TiN plug at the bottom of the feature, the molybdenum film may be deposited and grown from the bottom of the feature. In a second example, the molybdenum film may be deposited using the MoCl₅ precursor and the H₂ reactant, but at higher temperatures, i.e., above 800° C. This process window may have the molybdenum film deposited on both the dielectric and conductive surfaces within the feature. The deposition of the molybdenum film on the dielectric surface may be used to create a barrierless molybdenum layer in the feature.

In some embodiments, selective deposition is performed using a molybdenum oxyhalide precursor. As described above, the surface treatments described above significantly improve selectivity of Mo deposition from MoO₂Cl₂. As indicated above, examples of MoO_{y}X_{z} precursors include MoO₂Cl₂, MoOCH₄, MoOF₄, MoO₂Br₂, MoO₂I, and Mo₄O₁₁I. The feature may be filled using ALD, plasma enhanced ALD, chemical vapor deposition (CVD), or plasma enhanced CVD. For ALD or CVD, H₂ may be the reducing agent. Molybdenum deposits more quickly using a molybdenum oxyhalide precursor than the MoClₓ precursor used in the surface treatment. For example, a MoO_{y}X_{z} precursor may deposit molybdenum at a deposition rate at least twice as fast as a MoClₓ precursor for a non-plasma process. Plasma enhanced processes may be used to fill features at lower temperatures and/or increase deposition rates.

In some embodiments, filling a feature can involve depositing a nucleation layer. A nucleation layer is a thin layer that supports bulk deposition. It may be conformal to the feature.

In many embodiments, a nucleation layer is deposited by an ALD process. In some embodiments, a Mo nucleation layer is deposited using one or more of a boron-containing reducing agent (e.g., B₂H₆) or a silicon-containing reducing agent (e.g., SiH₄) as a co-reactant. For example, one or more S/Mo cycles or Mo/S cycles may be used to deposit a Mo nucleation layer. In another example, one or more B/Mo cycles or Mo/B cycles may be used to deposit a Mo nucleation layer on which a bulk Mo layer is deposited. B refers to a pulse of diborane or other boron-containing reducing agent and S to a pulse of silane or other silicon-containing reducing agent, such that S/Mo refers to a pulse of silane followed by a pulse of a Mo-containing precursor. B/Mo and S/Mo cycles (or Mo/B and/or Mo/S) may both be used to deposit a Mo nucleation layer, e.g., x(B/Mo)+y(S/Mo), with x and y being integers. Examples of boron-containing reactants include diborane (B₂H₆), alkyl boranes, alkyl boron, aminoboranes (CH₃)₂NB(CH₂)₂, carboranes such as C₂BₙHₙ₊₂, and other boranes. Examples of boranes include BₙHₙ₊₄, BₙHₙ₊₆, BₙHₙ₊₈, BₙHₘ, where n is an integer from 1 to 10, and m is a different integer than m. Examples of silicon-containing reducing agents including silane (SiH₄) and other silanes such as disilane (Si₂H₆).

In some embodiments, deposition of a Mo nucleation layer may involve using a non-oxygen-containing precursor, e.g., molybdenum hexafluoride (MoF₆) or molybdenum pentachloride (MoCl₅). Oxygen in oxygen-containing precursors may react with a silicon- or boron-containing reducing agent to form MoSiₓO_{y} or MoBₓO_{y}, which are impure, high resistivity films. In some embodiments, oxygen-containing precursors may be used for nucleation layer deposition with oxygen incorporation minimized. Oxygen incorporation can be minimized by high reducing agent flows (e.g., greater than 100:1 volumetric flow rate of reducing agent to oxygen-containing Mo precursor).

In some embodiments, H₂ may be used as a reducing gas for Mo nucleation layer deposition instead of a boron-containing or silicon-containing reducing gas. Example thicknesses for deposition of a Mo nucleation layer range from 5 Å to 30 Å. Films at the lower end of this range may not be continuous; however, as long as they can help initiate continuous bulk Mo growth, the thickness may be sufficient.

In some embodiments, the reducing agent pulses during deposition of a nucleation or bulk Mo layer may be done at lower substrate temperatures than the Mo precursor pulses. For example, or B₂H₆ or a SiH₄ (or other boron- or silicon-containing reducing agent) pulse may be performed at a temperature below 300° C., with the Mo pulse at temperatures greater than 300° C.

In some embodiments, the reducing agent is NH₃ or other nitrogen-containing reducing agents such as hydrazine (N₂H₄). NH₃ chemisorption on dielectrics is more favorable than that of H₂. In some embodiments, the reducing agent and precursor are selected such that they react without reducing agent dissociation. NH₃ reacts with metal oxychlorides and metal chlorides without dissociation. This is in contrast to, for example, ALD from metal oxychlorides that use H₂ as a reducing agent; H₂ dissociates on the surface to form adsorbed atomic hydrogen, which results in very low concentrations of reactive species and low surface coverage during initial nucleation of metal on the dielectric surface. By using NH₃ and metal oxychloride or metal chloride precursors, nucleation delay is reduced or eliminated at deposition temperatures up to hundreds of degrees lower than used by H₂ reduction of the same metal precursors.

In some embodiments, the reducing agent may be a boron-containing or silicon-containing reducing agent such as B₂H₆ or SiH₄. These reducing agents may be used with metal chloride precursors, with metal oxychlorides; however, the B₂H₆ and SiH₄ may react with water formed as a byproduct during the ALD process and form solid B₂O₃ and SiO₂. These are insulating and can remain in the film, increasing resistivity. Use of NH₃ also has improved adhesion over B₂H₆ and SiH₄ ALD processes on certain surfaces including Al₂O₃. The resulting nucleation layer is generally not a pure elemental film but a metal nitride or metal oxynitride film. In some embodiments, there may be residual chlorine or fluorine from the deposition, particularly if the deposition is performed at low temperatures. In some embodiments, there may be no more than a trace amount of residual chlorine or fluorine. In some embodiments, the nucleation layer is an amorphous layer. Impurities in the film (e.g., oxygen, NH₃, chlorine, or other halogens) facilitate the growth of an amorphous microstructure. In some embodiments, the nucleation layer as deposited is an amorphous molybdenum oxynitride layer or an amorphous molybdenum nitride layer. The amorphous character templates large grain growth in the subsequently deposited conductor. The surface energy of nitride or oxynitride relative to an oxide surface is much more favorable than that of a metal on an oxide surface, facilitating formation of a continuous and smooth film on the dielectric. This allows formation of thin, continuous layers. Example thicknesses of the nucleation layer range from 5-30 Å as deposited. Depending on the temperature, this may be about 5-50 ALD cycles, for example.

### Etch

Etch operations may be used in the methods for filling features with Mo films. Etch operations remove materials such as metals and nitrides from the feature. For example, an etch process may partially or completely remove a liner layer from a feature. In another example, the etch process may be used to reduce the thickness of a liner layer. The etch operation, in some embodiments, may involve soaking the feature soaked in a Mo halide. In some embodiments, an etch operation involves soaking the feature with a MoClₓ such as MoCl₅. In some embodiments, the soak may be done continuously with the Mo halide gas. In some embodiments, the soak may be pulsed, cycling the Mo halide with a purge gas, such as argon (Ar).

A MoClₓ precursor may be used for both deposition and etch operations. For example, in certain process windows, a MoCl₅ precursor may concurrently grow a Mo film and etch away a metal or metal compound film in the feature. The process is considered a net etch operation if the rate of material removed is greater than the material deposited by the precursor. The speed at which the precursor deposits material and etches material may be controlled by a variety of process conditions, including the type of reactant used and the process temperature. Generally speaking, the lower the temperature, the higher the ratio of etching away material is relative to deposition of material. At higher temperatures, the same precursor and reactant may be used as a net deposition operation, i.e., the amount of material deposited is greater than the material removed. For example, MoCl₅ precursor and H₂ reactant may be used in an etch operation when the process temperature is below 400° C. The same precursor of MoCl₅ and H₂ reactant may be used in a deposition operation when the process temperature is above 550° C.

In some embodiments, the MoClₓ precursor at high temperatures, e.g., above 550° C., may continue to etch material at a faster rate than depositing material. For example, MoCl₅ may be used to etch a feature by a soak without a reactant. In this example, the temperature may be as high as 700° C. and will continue to etch away material from the feature. In operations where the feature is soaked in a MoCl₅ without a reactant, the increased temperature may increase the rate at which material is etched from the feature.

A feature may have surface oxide or contaminants on it. For example, the surface of an underlying TiN, WN, or W layer may be oxidized. If left, the oxidized surface can result in higher resistivity. Clean operations are used to remove such oxides and contaminants. In some embodiments, the clean operation may have the feature soaked in a Mo precursor gas, typically a Mo halide. Similar to the etch operations described above, the precursor gas may be a MoClₓ precursor. In some embodiments, the soak may be done continuously. In some embodiments, the soak may be pulsed, cycling MoClₓ and a purge gas, such as argon (Ar). The precursor may be a non-oxygen Cl-containing Mo compound able to remove oxidation from the feature's surfaces. Examples of MoClₓ compounds are given above. A Cl-containing precursor may be used where traditional cleaning with thermal or plasma H₂ does not work, such as where the oxidized surface is stable on the surface material. A Cl-containing precursor is less likely to over-etch a feature's liner layer or attack a feature's surfaces than a F-containing compound.

### Apparatus

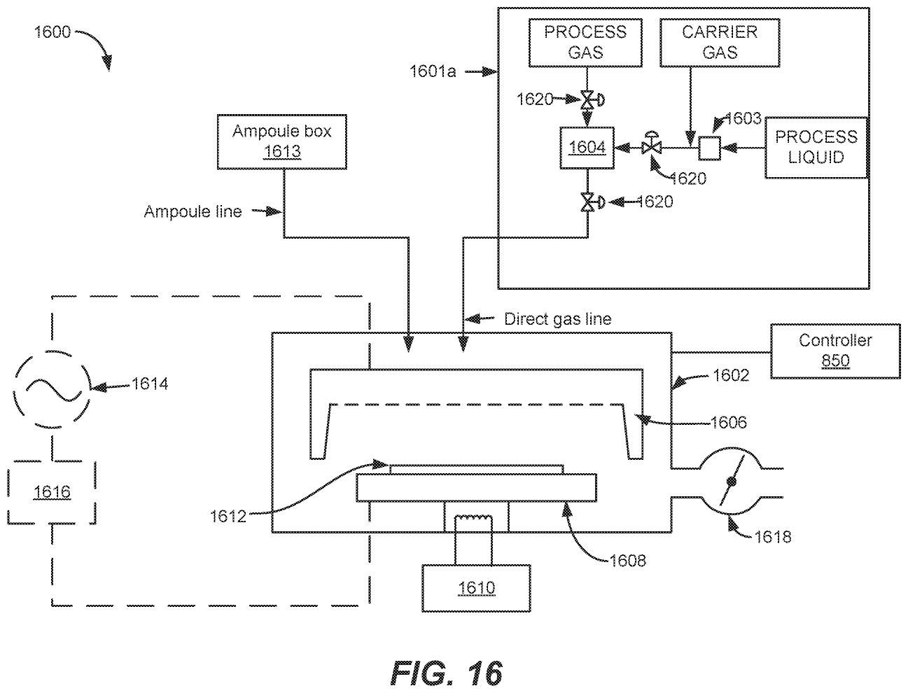

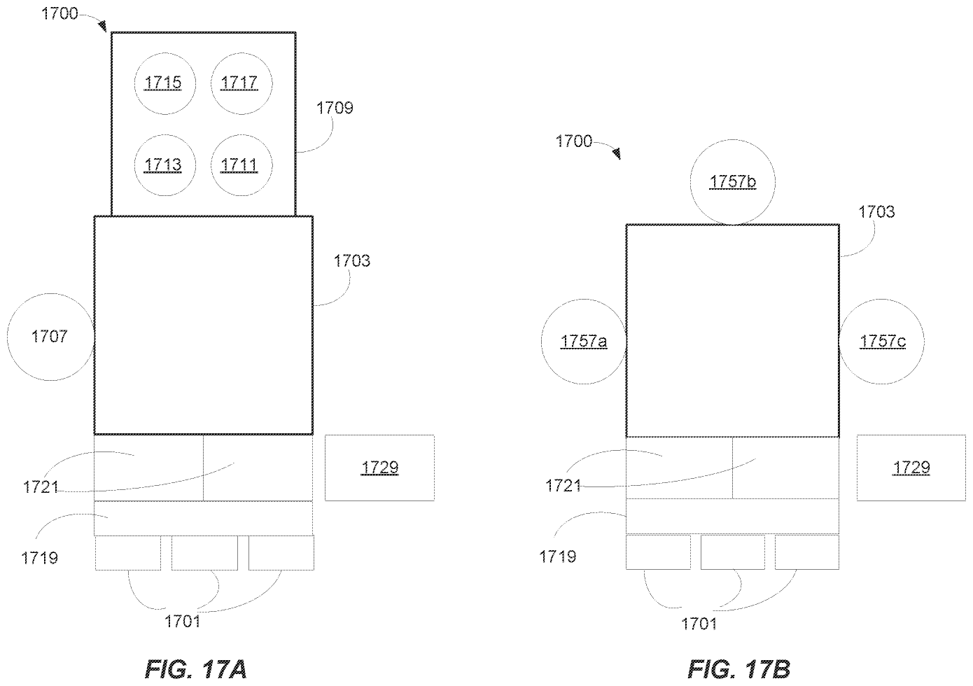

FIG. 16 depicts a schematic illustration of an embodiment of an ALD process station 1600 having a process chamber 1602 for maintaining a low-pressure environment. In some embodiments, a plurality of ALD process stations may be included in a common low-pressure process tool environment. For example, FIGS. 17A and 17B depict embodiments of a multi-station processing tool 1700. In some embodiments, one or more hardware parameters of ALD process station 1600, including those discussed in detail below, may be adjusted programmatically by one or more computer controllers 1750. In some other embodiments, a process chamber may be a single station chamber.

ALD process station 1600 fluidly communicates with reactant delivery system 1601a for delivering process gases to a distribution showerhead 1606. Reactant delivery system 1601 a includes a mixing vessel 1604 for blending and/or conditioning process gases, such as a Mo precursor-containing gas, a hydrogen-containing gas, an argon or other carrier gas, or other reactant-containing gas, for delivery to showerhead 1606. One or more mixing vessel inlet valves 1620 may control introduction of process gases to mixing vessel 1604. In various embodiments, deposition of an initial Mo layer is performed in process station 1600 and in some embodiments, other operations such as in-situ clean or Mo gap fill may be performed in the same or another station of the multi-station processing tool 1700 as further described below with respect to FIG. 17A.

As an example, the embodiment of FIG. 16 includes a vaporization point 1603 for vaporizing liquid reactant to be supplied to the mixing vessel 1604. In some embodiments, vaporization point 1603 may be a heated vaporizer. In some embodiments, a liquid precursor or liquid reactant may be vaporized at a liquid injector (not shown). For example, a liquid injector may inject pulses of a liquid reactant into a carrier gas stream upstream of the mixing vessel 1604. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 1603. In one scenario, a liquid injector may be mounted directly to mixing vessel 1604. In another scenario, a liquid injector may be mounted directly to showerhead 1606.

In some embodiments, a liquid flow controller (LFC) upstream of vaporization point 1603 may be provided for controlling a mass flow of liquid for vaporization and delivery to process chamber 1602. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 1606 distributes process gases toward substrate 1612. In the embodiment shown in FIG. 16, the substrate 1612 is located beneath showerhead 1606 and is shown resting on a pedestal 1608. Showerhead 1606 may have any suitable shape and may have any suitable number and arrangement of ports for distributing process gases to substrate 812.

In some embodiments, pedestal 1608 may be raised or lowered to expose substrate 1612 to a volume between the substrate 1612 and the showerhead 1606. In some embodiments, pedestal 1608 may be temperature controlled via heater 1610. Pedestal 1608 may be set to any suitable temperature, such as between about 250° C. and about 800° C. during operations for performing various disclosed embodiments. It will be appreciated that, in some embodiments, pedestal height may be adjusted programmatically by a suitable computer controller 850. At the conclusion of a process phase, pedestal 1608 may be lowered during another substrate transfer phase to allow removal of substrate 1612 from pedestal 1608.

In some embodiments, a position of showerhead 1606 may be adjusted relative to pedestal 1608 to vary a volume between the substrate 1612 and the showerhead 1606. Further, it will be appreciated that a vertical position of pedestal 1608 and/or showerhead 1606 may be varied by any suitable mechanism within the scope of the present disclosure. In some embodiments, pedestal 1608 may include a rotational axis for rotating an orientation of substrate 1612. It will be appreciated that, in some embodiments, one or more of these example adjustments may be performed programmatically by one or more suitable computer controllers 1650. The computer controller 1650 may include any of the features described below with respect to controller 1650 of FIG. 16.

In some embodiments where plasma may be used as discussed above, showerhead 1606 and pedestal 1608 electrically communicate with a radio frequency (RF) power supply 1614 and matching network 1616 for powering a plasma. In some embodiments, the plasma energy may be controlled by controlling one or more of a process station pressure, a gas concentration, an RF source power, an RF source frequency, and a plasma power pulse timing. For example, RF power supply 1614 and matching network 1616 may be operated at any suitable power to form a plasma having a desired composition of radical species. Likewise, RF power supply 1614 may provide RF power of any suitable frequency. In some embodiments, RF power supply 1614 may be configured to control high- and low-frequency RF power sources independently of one another. Example low-frequency RF frequencies may include, but are not limited to, frequencies between 0 kHz and 900 kHz. Example high-frequency RF frequencies may include, but are not limited to, frequencies between 1.8 MHz and 2.45 GHZ, or greater than about 13.56 MHz, or greater than 27 MHz, or greater than 80 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 1650 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., a Mo precursor), instructions for setting a flow rate of a carrier gas (such as argon), and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for modulating a flow rate of a second reactant gas such as H₂, instructions for modulating the flow rate of a carrier or purge gas, instructions for igniting a plasma, and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. It will be appreciated that these recipe phases may be further subdivided and/or iterated in any suitable way within the scope of the present disclosure.

Further, in some embodiments, pressure control for process station 1600 may be provided by butterfly valve 1618. As shown in the embodiment of FIG. 16, butterfly valve 1618 throttles a vacuum provided by a downstream vacuum pump (not shown). However, in some embodiments, pressure control of process station 1600 may also be adjusted by varying a flow rate of one or more gases introduced to the process station 1600.

FIG. 17A and FIG. 17B show examples of processing systems. FIG. 17A shows an example of a processing system including multiple chambers. The system 1700 includes a transfer module 1703. The transfer module 1703 provides a clean, vacuum environment to minimize risk of contamination of substrates being processed as they are moved between various modules. Mounted on the transfer module 1703 is a multi-station chamber 1709 capable of performing in-situ clean and/or ALD processes described above. Surface treatment and/or initial Mo layer deposition may be performed in the same or different station or chamber as the subsequent Mo gap fill.

Chamber 1709 may include multiple stations 1711, 1713, 1715, and 1717 that may sequentially perform operations in accordance with disclosed embodiments. For example, chamber 1709 may be configured such that station 1711 performs an in-situ treatment using a MoClₓ precursor. Station 1713 may be configured to selectively treat the field region and upper sidewalls and stations 1715 and 1717 may be configured to perform ALD of bulk Mo using an molybdenum oxyhalide precursor and H₂. In another example, chamber 1709 may be configured such that station 1711 performs in-situ clean, station 1713 performs ALD of an initial Mo layer, station 1713 selectively treats the layer, and 1714 deposition of bulk Mo. In another example, the chamber 1709 may be configured to do parallel processing of substrates, with each station performing multiple processes sequentially.

Two or more stations may be included in a multi-station chamber, e.g., 2-6, with the operations appropriately distributed. For example, a two-station chamber may be configured to perform ALD of an initial Mo layer in a first station followed by ALD of bulk Mo in a second station. Stations may include a heated pedestal or substrate support, one or more gas inlets or showerhead or dispersion plate.

Also mounted on the transfer module 1703 may be one or more single or multi-station modules 1707. In some embodiments, a preclean as described above may be performed in a module 1707, after which the substrate is transferred under vacuum to another module (e.g., another module 1707 or chamber 1709) for ALD. In another example, a module for selective treatment of a film may be mounted on the transfer module. An example is shown in FIG. 10.

The system 1700 also includes one or more wafer source modules 1701, where wafers are stored before and after processing. An atmospheric robot (not shown) in the atmospheric transfer chamber 1719 may first remove wafers from the source modules 1701 to loadlocks 1721. A wafer transfer device (generally a robot arm unit) in the transfer module 1703 moves the wafers from loadlocks 1721 to and among the modules mounted on the transfer module 1703.

In some embodiments, ALD of Mo is performed in a first chamber, which may be part of a system like system 1700, with CVD or PVD of W or Mo or other conductive material deposited as an overburden layer performed in another chamber, which may not be coupled to a common transfer module, but part of another system.

FIG. 17B is an embodiment of a system 1700. The system 1700 in FIG. 17B has wafer source modules 1701, a transfer module 1703, atmospheric transfer chamber 1719, and loadlocks 1721, as described above with reference to FIG. 17A. The system in FIG. 17B has three single station modules 1757a-1775c. The system 1700 may be configured to sequentially perform operations in accordance with disclosed embodiments. For example, the single station modules 1757a-1757c may be configured so that a first module 1757a performs a surface treatment, a second module 957b performs ALD of an initial Mo layer using a molybdenum halide precursor, and a third module 957c performs ALD of bulk Mo using a molybdenum oxyhalide precursor. In this example, an in-situ clean may be optionally performed in second module 1757b instead of or in addition to a preclean in first module 1757a. In another example, the single station modules 1757a-1757c may be configured so that a first module 1757a performs a deposition of an initial metal layer, a second module 1757b performs selective treatment, and a third module 1757c performs ALD of bulk Mo using a molybdenum oxyhalide precursor. In yet another example, one module may be configured for deposition, another module for selective treatment, and another module for etch.

Stations may include a heated pedestal or substrate support, one or more gas inlets or showerhead or dispersion plate as described above with reference to FIG. 16.

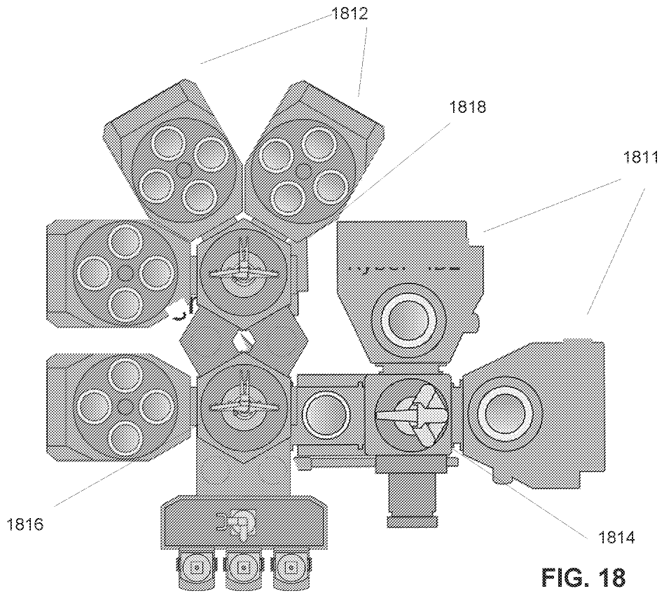

FIG. 18 shows an example of system that includes ion plasma modules 1811, vapor deposition modules 1812, and transfer modules 1814, 1816, and 1818. In some embodiments, an apparatus may have two or more transfer modules with ion plasma modules attached to a first transfer module and vapor deposition modules attached to a second transfer module. An intermediate transfer module (such as transfer module 1816) can be employed to transfer substrates between an ion plasma module and a deposition module. The system may be configured to selectively treat a substrate as described above in an ion plasma module 1811 followed by Mo deposition in a vapor deposition module 1812. Deposition of a Mo liner, a W liner, or other liner in a deposition module 1812 may precede the selective treatment. In some embodiments, an etch operation as described above with respect to FIGS. 12 and 13D may be performed in an ion plasma module 1811.

An example of an ion plasma module is shown is FIG. 19, which presents a simplified cross-sectional view of an ion beam etch system 1900 for performing ion beam etching and/or ion beam treatment such as oxidation or nitridation according to certain methods. In this example, wafer 1901 rests on the substrate support 1903. The substrate support may provide clamping such as mechanical clamping or electrostatic clamping to hold the wafer 1101 on the substrate support 1903. The ion beam etch system 1900 may be equipped with hardware (not shown) to provide electrical and fluidic connections. The electrical connections may be used to supply electricity to the substrate support 1903 or to an electrostatic chuck located on or within the substrate support 1903 in some cases, while the fluidic connections may be used to provide fluids used to control the temperature of the wafer 1901 and substrate support 1903. The substrate support 1903 may be heated by a heater (not shown) and/or cooled by a cooling mechanism (not shown). Any appropriate cooling mechanism may be used. In one example, the cooling mechanism may involve flowing cooling fluids through piping in or adjacent to the substrate support 1903. The substrate support 1903 may be capable of rotating and tilting at variable speeds and angles as described above with respect to FIG. 15. A position controller 1932 may be used to control the tilt and rotation of the substrate support 1903. The substrate support 1903 and wafer 1901 are within a processing chamber 1915.

The processing chamber 1915 is separated from a plasma source chamber 1905 by an ion extractor 1912. In this embodiment, the ion extractor 1912 comprises a first electrode 1909, a second electrode 1911, and a third electrode 1913. In this embodiment, the third electrode 1913 is grounded. In other embodiments, the ion extractor 1912 may be other combinations of electrodes for extracting ions from the plasma source chamber 1905. In some embodiments, the ion extractor 1912 is able to provide an ion beam from the plasma source chamber 1905. The plasma source chamber 1905 is surrounded by a coil 1907. The coil 1907 is electrically connected to a matching network 1924 and a radio frequency (RF) source 1920. The coil 1907, matching network 1924, and RF source 1920 provide an RF power system for providing RF power to the plasma source chamber 1905. A gas inlet 1908 is at an end of the plasma source chamber 1905. The gas inlet 1908 is in fluid connection with a process gas source 1902 and a cleaning gas source 1904 through at least one manifold 1906. The gas inlet 1908 may be in one of many different forms. For example, the gas inlet may be a gas distribution plate, a gas diffuser plate, a showerhead, or a gas injector. A turbopump 1928 may be in fluid connection to the processing chamber 1915 to remove gas from and control the pressure in the processing chamber 1915.

In some embodiments, a switch 1916 may be in fluid connection between the process gas source 1902, the cleaning gas source 1904, and the gas inlet 1908. The switch 1916 may be any device or group of devices that are adapted to switch to provide process gas from the process gas source 1902 during wafer processing and cleaning gas from the cleaning gas source 1904 during the chamber clean.

As described above, an ion beam etch system 1900 may be used for selective oxidation or selective nitridation using a mild plasma and appropriate rotation and tilt of the substrate. Examples of process gases for oxidation include oxygen (O₂), ozone (O₃), nitrous oxide (N₂O), mixtures of H₂ and O₂, N₂ and O₂, and NH₃ and O₂. Examples of process gases for nitridation include nitrogen (N₂) and ammonia (NH₃), and mixtures of H₂ and N₂, N₂ and O₂, and NH₃ and O₂ Plasma conditions are mild to treat without etching the surface in some embodiments. Examples of mild plasma conditions include less than 100V bias voltage, less than 200 mA source current, less than 500 W source power, and 0-20 sccm O₂ flow per station.

Ion beam etch system 1900 may be controlled using a controller 1914, which may have characteristics and features similar to that of system controller 1729 of FIGS. 17A and 17B.

Returning to FIGS. 17A and 17B, in various embodiments, a system controller 1729 is employed to control process conditions during deposition. The controller 1729 will typically include one or more memory devices and one or more processors. A processor may include a CPU or computer, analog and/or digital input/output connections, stepper motor controller boards, etc. Such a system controller may be employed in control of any of the processes and apparatus described herein.

The controller 1729 may control all the activities of the apparatus. The system controller 1729 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 1729 may be employed in some embodiments.

Typically, there will be a user interface associated with the controller 1729. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general-purpose processor. System control software may be coded in any suitable computer readable programming language.

The computer program code for controlling the Mo precursor pulses, hydrogen pulses, and argon flow, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 1729. The signals for controlling the process are output on the analog and digital output connections of the deposition apparatus.

The system software may be designed or configured in many ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 1729 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 1729, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 1729, in some implementations, may be a part of or coupled to a computer that is integrated with, coupled to the system, otherwise networked to the system, or a combination thereof. For example, the controller 1729 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a PVD chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 1729 may include various programs. A substrate positioning program may include program code for controlling chamber components that are used to load the substrate onto a pedestal or chuck and to control the spacing between the substrate and other parts of the chamber such as a gas inlet. A substrate tilt and rotation program may include for tilt and rotation. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

1. A method, comprising:
providing a substrate comprising a feature comprising a metal-containing contact and dielectric sidewalls;
treating the feature by exposing it to a molybdenum halide; and
depositing molybdenum in the feature, wherein the deposition is selective to the metal-containing contact with respect to the dielectric sidewalls.

2. The method of claim 1, further comprising exposing the feature to a hydrogen-containing plasma prior to treating the feature.

3. The method of claim 1, wherein depositing molybdenum in the feature exposing the feature to a molybdenum oxyhalide.

4. The method of claim 1, wherein the treatment inhibits molybdenum growth on the dielectric sidewalls.

5. The method of claim 1, wherein the treatment is performed without depositing molybdenum in the feature.

6. The method of claim 1, wherein the treatment further comprises exposing the feature to a co-reactant capable of reducing the molybdenum halide to form molybdenum.

7. The method of claim 1, wherein an amorphous molybdenum-containing layer is on the metal-containing contact.

8. The method of claim 7, wherein the treatment removes the amorphous molybdenum-containing layer.

9. A method, comprising:
providing a substrate comprising a feature having dielectric sidewalls and a molybdenum contact; comprising a molybdenum contact and dielectric sidewalls, wherein an amorphous molybdenum-containing layer is at the surface of the molybdenum contact;
exposing the feature to a molybdenum halide to remove the amorphous molybdenum-containing layer and inhibit molybdenum deposition on the dielectric sidewalls; and
depositing molybdenum in the feature, wherein the deposition is selective to the molybdenum contact with respect to the dielectric sidewalls.

10. A method, comprising:
(a) providing a substrate comprising a field region and a feature, wherein the feature comprises an opening, sidewalls, and a bottom, wherein the field region surrounds the opening, and wherein a liner layer lines the sidewalls of the feature;
(b) selectively treating the liner layer such that a portion of the liner layer on the field region and/or an upper portion of the sidewalls is preferentially treated with respect to the liner layer on a lower portion of the sidewalls, wherein selectively treating the liner layer forms selectively treated portions of the liner layer; and
(c) selectively depositing molybdenum at the bottom of the feature, wherein deposition on the selectively treated portions of the liner layer is inhibited.
